(19) United States
(12) Patent Application Publication
(10) Pub. No.: US 2025/0374678 A1
(43) Pub. Date: Dec. 4, 2025

(54) ARRAY SUBSTRATE AND DISPLAY DEVICE

(71) Applicant: Sharp Display Technology Corporation, Kameyama City (JP)

(72) Inventors: Yoshimizu MORIYA, Kameyama City (JP); Tomoyuki NISHIHAMA, Kameyama City (JP); Takumi TOMITA, Kameyama City (JP); Kenichi NISHIMURA, Kameyama City (JP)

(21) Appl. No.: 19/201,788

(22) Filed: May 7, 2025

(30) Foreign Application Priority Data
May 31, 2024 (JP) 2024-089109

(51) Int. Cl. H10D 86/40; G02F 1/1362; G02F 1/1368; H10D 86/60

(52) U.S. Cl. CPC H10D 86/443; G02F 1/136286; G02F 1/1368; H10D 86/471; H10D 86/60

(57) ABSTRACT

An array substrate includes a first line extending along a first direction, a second line extending along a second direction that crosses the first direction, a first electrode, and a first insulating film. The first line includes a first line section and a second line section each of which is a portion of a first conductive film, and a first connection electrode that is a portion of a second conductive film. Each of the second line and the first electrode is a portion of the second conductive film. The first line section includes a first end portion. The second line section includes a second end portion that is away from the first end portion in the second direction and is between the second line and the first electrode in the first direction. The first connection electrode extends from the first end portion to the second end portion.

### CROSS REFERENCE TO RELATED APPLICATION

This application claims priority from Japanese Patent Application No. 2024-089109 filed on May 31, 2024. The entire contents of the priority application are incorporated herein by reference.

### TECHNICAL FIELD

The present technology described herein relates to an array substrate and a display device that achieve high resolution.

### BACKGROUND

One example of an array substrate included in a liquid crystal panel includes a light transmissive substrate, a switching component disposed on the light transmissive substrate, a gate electrode line including segment parts and connected to the switching component, and a conductive portion that is included in a layer different from the gate electrode line and electrically connects the segment parts of the gate electrode line.

In such an array substrate, the conductive portion is made of a material same as that of signal electrode lines and drain electrodes of the switching components. Therefore, a sufficient space is necessary between the conductive portion and the signal electrode line to avoid a short circuit between the conductive portion and the signal electrode line. Also, a sufficient space is necessary between the conductive portion and the drain electrode to avoid a short circuit between the conductive portion and the drain electrode. Therefore, a total space of the two spaces and a space for a length of the conductive portion need to be provided between the signal electrode line and the drain electrode. This may hinder short interval arrangement of pixels and high resolution is less likely to be achieved.

### SUMMARY

The technology described herein was made in view of the above circumstances. An object is to achieve high resolution.

(1) An array substrate according to the technology described herein includes a first line extending along a first direction, a second line extending along a second direction that crosses the first direction, a first electrode that is spaced from the first line in the second direction and is spaced from the first source line in the first direction, and a first insulating film. The first line includes a first line section, a second line section, and a first connection electrode. The first line section is a portion of a first conductive film that is disposed in a layer lower than the first insulating film. The second line section is a portion of the first conductive film that is different from the portion of the first conductive film configured as the first line section. The first connection electrode is a portion of a second conductive film that is disposed in a layer upper than the first insulating film. The second line is a portion of the second conductive film that is different from the portion of the second conductive film configured as the first connection electrode. The first electrode is a portion of the second conductive film that is different from the portions of the second conductive film configured as the first connection electrode and the second line. The first line section includes a first end portion. The second line section includes a second end portion that is away from the first end portion in the second direction and on a same side as the first electrode with respect to the second direction. The second end portion is between the second line and the first electrode in the first direction. The first connection electrode extends from the first end portion to the second end portion. The first insulating film includes a first contact hole in a portion overlapping the first end portion and the first connection electrode and a second contact hole in a portion overlapping the second end portion and the first connection electrode.

(2) In the array substrate, in addition to (1), the first line section may extend along the first direction and the second line section may include a body section and a bent section. The body section may extend along the first direction and extend on a same straight line as the first line section extends and the bent section may extend from the body section with being bent to the second end portion.

(3) In the array substrate, in addition to (2), the bent section may be between the first connection electrode and the second line in the first direction.

(4) In the array substrate, in addition to any one of (1) to (3), the first end portion and the second end portion may be disposed to overlap with respect to the second direction.

(5) The array substrate may further include, in addition to any one of (1) to (4), a first switching component including the first electrode and a first pixel electrode that is connected to the first electrode. The first switching component may include a second electrode that is a portion of the first line section. The first pixel electrode may include a first connection portion that is connected to the first electrode and a first pixel electrode body that is disposed on an opposite side from the first line with respect to the first connection portion in the second direction. The first connection electrode may be disposed between the first line section and the first pixel electrode body with respect to the second direction.

(6) The array substrate may further include, in addition to any one of (1) to (5), a first switching component including the first electrode, a first pixel electrode that is connected to the first electrode, a second insulating film that is disposed in a layer lower than the first pixel electrode, and a common electrode that is included in a layer lower than the second insulating film to overlap the first pixel electrode.

The first switching component may include a second electrode that is a portion of the first line section. The common electrode may include an opening that surrounds the first electrode and an overlapping portion that overlaps the first connection electrode.

(7) In the array substrate, in addition to (6), the opening of the common electrode may include a first slit and a second slit. The first slit may extend along the first direction toward the first connection electrode. The second slit may extend along the first direction toward an opposite side from the first connection electrode and may be longer than the first slit.

(8) The array substrate may further include, in addition to any one of (1) to (7), a first switching component including the first electrode, a first pixel electrode that is connected to the first electrode, a third line extending along the second direction and disposed on an opposite side from the first electrode with respect to the second line in the first direction and spaced from the second line, a third electrode that is disposed on a same side as the first electrode with respect to the first line in the second direction and is spaced from the first line with respect to the second direction and is disposed between the second line and the third line in the first direction, a second switching component including the third electrode, and a second pixel electrode that is connected to the third electrode. The first switching component may include a second electrode that is a portion of the first line section. The second switching component may include a fourth electrode that is a portion of the second line section. The third line may be a portion of the second conductive film that is different from the portions of the second conductive film configured as the first connection electrode, the second line, and the first electrode. The third electrode may be a portion of the second conductive film that is different from the portions of the second conductive film configured as the first connection electrode, the first source line, the first electrode, and the third line. The second line section may cross each of the second line and the third line via the first insulating film.

(9) The array substrate may further include, in addition to (8), a fourth line that extends along the second direction and is disposed such that the first pixel electrode is between the fourth line and the second line with respect to the first direction, a fifth line that extends along the second direction and is disposed on an opposite side from the second line with respect to the third line in the first direction and spaced from the third line, a sixth line that extends along the second direction and is disposed on a third line side with respect to the fifth line with respect to the first direction and spaced from the fifth line, a fifth electrode that is disposed on a same side as the first electrode with respect to the first line in the second direction and spaced from the first line and is between the fifth line and the sixth line in the first direction, a third switching component including the fifth electrode, a third pixel electrode that is disposed between the fifth line and the sixth line in the first direction and connected to the fifth electrode, and a signal supply section configured to supply image signals to each of the second line, the third line, the fourth line, the fifth line, and the sixth line. The first line may include a third line section and a second connection electrode. The third line section may be a portion of the first conductive film that is different from the portions of the first conductive film configured as the first line section and the second line section. The second connection electrode may be a portion of the second conductive film that is different from the portions of the second conductive film configured as the first connection electrode, the second line, the first electrode, and the third line. The fourth line may be a portion of the second conductive film that is different from the portions of the second conductive film configured as the first connection electrode, the second line, the first electrode, the third line, and the second connection electrode. The fifth line may be a portion of the second conductive film that is different from the portions of the second conductive film configured as the first connection electrode, the second line, the first electrode, the third line, the second connection electrode, and the fourth line. The sixth line may be a portion of the second conductive film that is different from the portions of the second conductive film configured as the first connection electrode, the second line, the first electrode, the third line, the second connection electrode, the fourth line, and the fifth line. The fifth electrode may be a portion of the second conductive film that is different from the portions of the second conductive film configured as the first connection electrode, the second line, the first electrode, the third source line, the second connection electrode, the fourth line, the fifth line, and the sixth line. The second line section may include a third end portion that is on an opposite side from the second end portion. The third line section may include a fourth end portion that is disposed on a same side as the fifth electrode with respect to the third end portion in the second direction and is disposed between the fifth electrode and the fifth line with respect to the first direction. The second connection electrode may extend from the third end portion to the fourth end portion. The first insulating film may include a third contact hole in a portion overlapping the third end portion and the second connection electrode and a fourth contact hole in a portion overlapping the fourth end portion and the second connection electrode. The first switching component may include a sixth electrode that is a portion of the fourth line and a first semiconductor section that is made of semiconductor material and connected to the first electrode and the sixth electrode. The third switching component may include a seventh electrode that is a portion of the second line section, an eighth electrode that is a portion of the sixth source line, and a third semiconductor section that is made of semiconductor material and connected to the fifth electrode and the sixth electrode. At least the image signals supplied from the signal supply section to the fourth line and the sixth line may have opposite polarities.

(10) A display device according to the technology described herein includes the array substrate according to any one of (1) to (9) and an opposed substrate opposed to and spaced from the array substrate.

According to the technology described herein, high resolution can be achieved.

### BRIEF DESCRIPTION OF THE DRAWINGS

FIG. 1 is a plan view illustrating a liquid crystal panel, a driver, and a flexible substrate included in a liquid crystal display device according to a first embodiment.

FIG. 2 is a cross-sectional view of the liquid crystal panel, the driver, and the flexible substrate according to the first embodiment.

FIG. 3 is a circuit diagram illustrating an electrical configuration of an array substrate included in the liquid crystal panel according to the first embodiment.

FIG. 4 is a plan view illustrating pixel arrangement of the array substrate according to the first embodiment.

FIG. 5 is a cross-sectional view of the liquid crystal panel according to the first embodiment along v-v line in FIG. 4.

FIG. 6 is a cross-sectional view of the liquid crystal panel according to the first embodiment along vi-vi line in FIG. 4.

FIG. 7 is an enlarged plan view a portion of the array substrate near a connection electrode according to the first embodiment.

FIG. 8 is a cross-sectional view of the liquid crystal panel according to the first embodiment along viii-viii line in FIG. 7.

FIG. 9 is a plan view illustrating a liquid crystal panel, a driver, and a flexible substrate included in a liquid crystal display device according to a second embodiment.

FIG. 10 is a plan view illustrating pixel arrangement of an array substrate according to the second embodiment.

FIG. 11 is a cross-sectional view of the liquid crystal panel according to the second embodiment along xi-xi line in FIG. 10.

FIG. 12 is a plan view illustrating pixel arrangement of an array substrate according to a third embodiment.

FIG. 13 is a plan view illustrating pixel arrangement of an array substrate according to a fourth embodiment.

FIG. 14 is a plan view schematically illustrating pixel arrangement of pixel rows of the array substrate according to the fourth embodiment and illustrating polarities of image signals supplied to the pixel electrodes during a certain frame period.

FIG. 15 is a plan view schematically illustrating pixel arrangement of pixel rows of an array substrate according to a fifth embodiment and illustrating polarities of image signals supplied to the pixel electrodes during a certain frame period.

FIG. 16 is a plan view illustrating pixel arrangement of an array substrate according to a sixth embodiment.

FIG. 17 is a plan view illustrating pixel arrangement of a pixel row of the array substrate according to the sixth embodiment different from that in FIG. 6.

FIG. 18 is a plan view schematically illustrating pixel arrangement of pixel rows of the array substrate according to the sixth embodiment and illustrating polarities of image signals supplied to the pixel electrodes during a certain frame period.

FIG. 19 is a plan view schematically illustrating pixel arrangement of pixel rows of an array substrate according to a seventh embodiment and illustrating polarities of image signals supplied to the pixel electrodes during a certain frame period.

### DETAILED DESCRIPTION

### First Embodiment

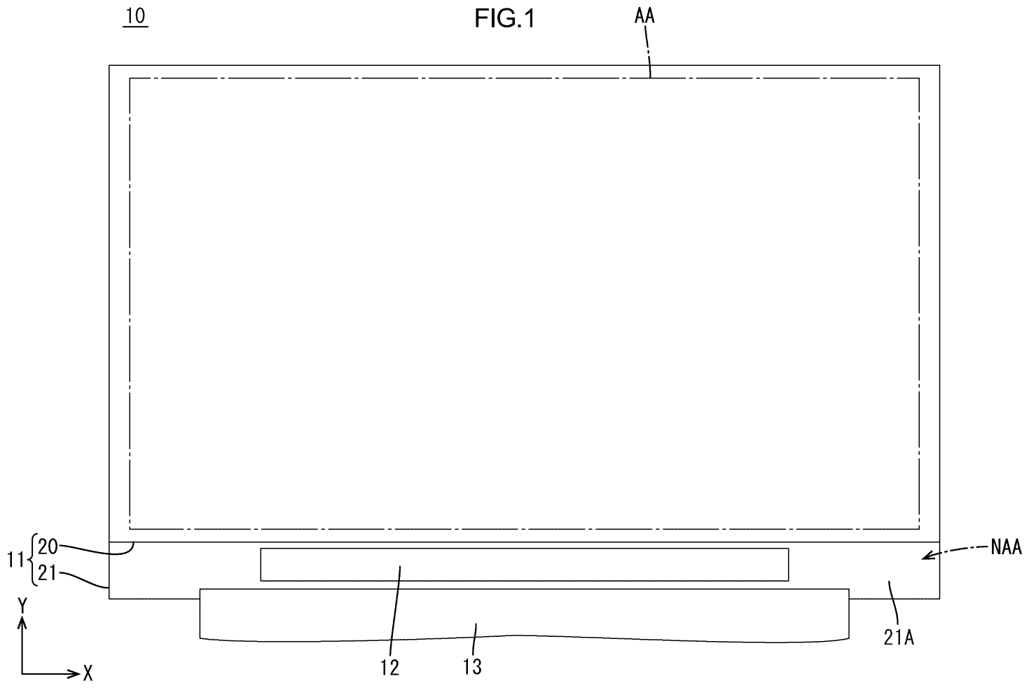

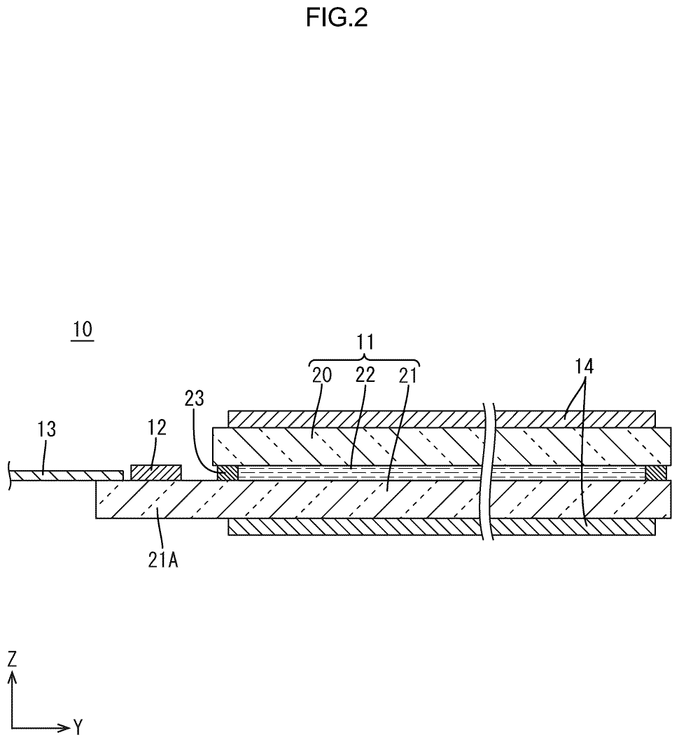

A first embodiment will be described with reference to FIGS. 1 to 8. In this embodiment section, a liquid crystal display device 10 will be described. X-axes, Y-axes, and Z-axes may be present in the drawings. The axes in each drawing correspond to the respective axes in other drawings. An upper side and a lower side in FIGS. 2, 5, 6, and 8 correspond to a front side and a back side of the liquid crystal display device 10, respectively.

As illustrated in FIG. 1, the liquid crystal display device 10 at least includes a liquid crystal panel 11 (a display device, a display panel) that has a laterally long rectangular shape and displays an image and a backlight unit (a lighting device) that supplies light to the liquid crystal panel 11 for displaying. The backlight unit is disposed behind (on a back surface side of) the liquid crystal panel 11. The backlight unit includes light sources configured to emit white light (e.g., LEDs) and optical members for converting the light from the light sources into planar light by applying optical effects to the light from the light sources. A middle section of a surface of the liquid crystal panel 11 is configured as a display area AA in which images are displayed. An outer section in a frame shape surrounding the display area AA in the surface of the liquid crystal panel 11 is configured as a non-display area NAA in which the images are not displayed.

The liquid crystal panel 11 will be described in detail with reference to FIGS. 1 and 2. As illustrated in FIGS. 1 and 2, the liquid crystal panel 11 includes a pair of substrates 20, 21 that are bonded to each other. One of the substrates 20, 21 on the front side is an opposed substrate 20 and another one on the back side is an array substrate 21. The opposed substrate 20 and the array substrate 21 include glass substrates and various kinds of films are formed in layers on an inner surface side the glass substrates. A liquid crystal layer 22 is disposed between the substrates 20 and 21. The liquid crystal layer 22 includes liquid crystal molecules having optical characteristics that vary according to application of electric field. A sealing portion 23 is disposed between the outer peripheral portions of the substrates 20, 21 for sealing the liquid crystal layer 22. The sealing portion 23 is formed in a rectangular frame shape and surrounds the liquid crystal layer 22. Polarizing plates 14 are attached to outer surfaces of the substrates 20 and 21.

As illustrated in FIGS. 1 and 2, the opposed substrate 20 has a short-side dimension that is smaller than a short-side dimension of the array substrate 21. The opposed substrate 20 is bonded to the array substrate 21 such that one of the long sides of the opposed substrate 20 is aligned with a corresponding one of the long sides of the array substrate 21. Therefore, a long side edge section including another one of the long sides of the array substrate 21 projects from another one of the long sides of the opposed substrate 20 and a projecting long side edge section is an uncovered section 21A. An entire area of the uncovered section 21A is the non-display area NAA and a driver 12 and a flexible substrate 13 for supplying various kinds of signals are mounted on the uncovered section 21A.

The driver 12 is an LSI chip including a driver circuit therein. The driver 12 is mounted on the uncovered section 21A of the array substrate 21 through the chip-on-glass (COG) technology. The driver 12 processes the various kinds of signals transmitted from the flexible substrate 13. As illustrated in FIGS. 1 and 2, the driver 12 is disposed adjacent to an edge extending in the X-axis direction and is between the flexible substrate 13 and the display area AA. The driver 12 has a laterally long rectangular plan view shape. The driver 12 is a component for supplying various kinds of signals to source lines 27 of the array substrate 21. The flexible substrate 13 includes a synthetic resin substrate (e.g., polyimide-based resin substrate) having insulating property and flexibility and multiple traces formed on the substrate. A first end of the flexible substrate 13 is connected to the uncovered section 21A of the array substrate 21 and a second end of the flexible substrate 13 is connected to an external circuit board (a control board).

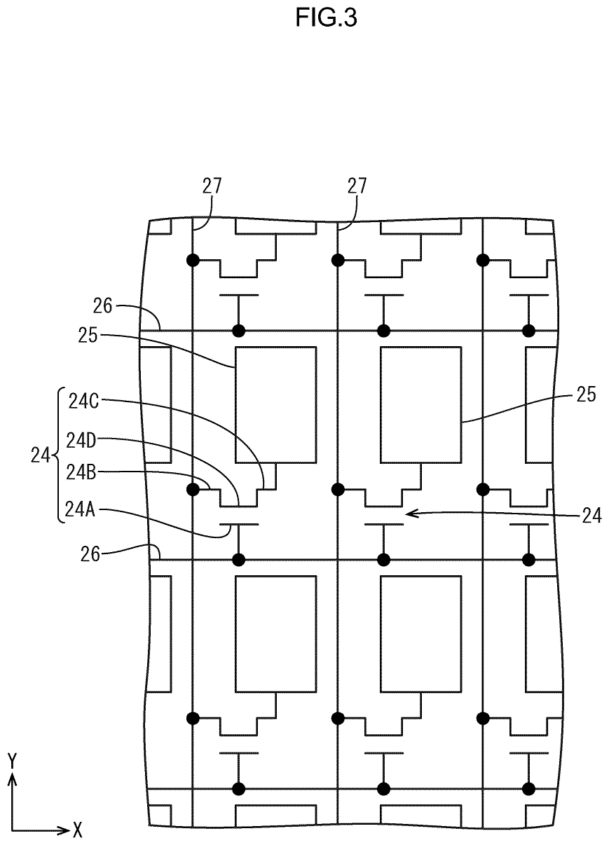

Next, a configuration of the array substrate 21 in the display area AA will be described with reference to FIG. 3. As illustrated in FIG. 3, thin film transistors (TFTs) 24 (transistors, switching components) and pixel electrodes 25 are at least arranged in an area of an inner surface of the array substrate 21 in the display area AA. The TFTs 24 and the pixel electrodes 25 are arranged at intervals in a matrix (rows and columns) along the X-axis direction and the Y-axis direction. Gate lines 26 (scanning lines, first lines) and source lines 27 (image lines, signal lines) are routed perpendicular to each other (with crossing) to surround the TFTs 24 and the pixel electrodes 25. The gate lines 26 extend substantially along the X-axis direction (a first direction) and are arranged at intervals with respect to the Y-axis direction. The source lines 27 extend in a direction substantially along the Y-axis direction (a second direction) and are arranged at intervals with respect to the X-axis direction. The TFT 24 includes a gate electrode 24A that is connected to the gate line 26, a source electrode 24B that is connected to the source line 27, a drain electrode 24C that is connected to the pixel electrode 25, and a semiconductor section 24D that is connected to the source electrode 24B and the drain electrode 24C. The TFTs 24 are driven based on scan signals supplied to the gate electrodes 24A through the gate lines 26. The scan signals include a potential higher than threshold voltage of the TFT 24. Through the driving of the TFT 24, a potential related to the image signal that is supplied to the source electrode 24B through the source line 27 is supplied to the drain electrode 24C via the semiconductor section 24D. As a result, the pixel electrode 25 is charged at the potential related to the pixel signal. The pixel electrode 25 is arranged in an area surrounded by the gate lines and the source lines 27.

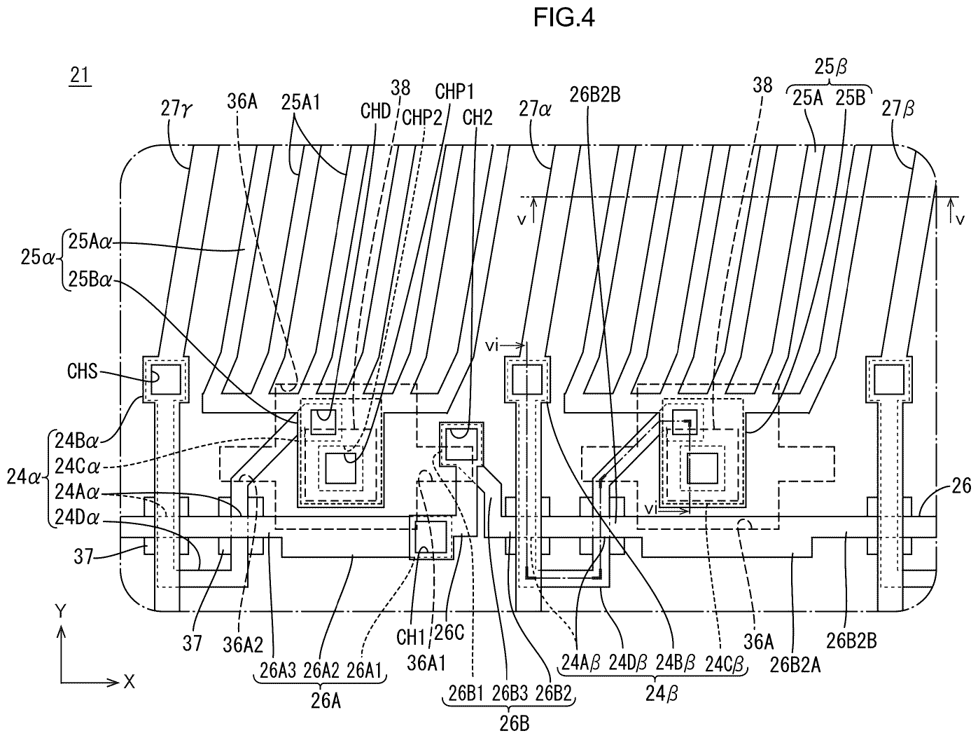

A detailed planar configuration of the array substrate 21 in the display area AA will be described with reference to FIG. 4. As illustrated in FIG. 4, the gate line 26 extends substantially straight along the X-axis direction and includes wide sections. The gate line 26 includes narrow sections that cross the source lines 27 or the semiconductor sections 24D of the TFTs 24 and includes the wide sections that are next to the drain electrodes 24C of the TFTs 24. The source lines 27 extend substantially along the Y-axis direction as a whole. The source line 27 includes a straight portion that extends along the Y-axis direction and an inclined portion that is inclined slightly with respect to the Y-axis direction. The straight portion of the source line 27 crosses the gate line 26 and the rest portion of the source line 27 is the inclined portion. The pixel electrode 25 includes a pixel electrode body 25A and a connection portion 25B. The pixel electrode body 25A has a vertically long plan view shape. The connection portion 25B is connected to the drain electrode 24C of the TFT 24. The pixel electrode body 25A includes two end portions in the elongated direction and the two end portions of the pixel electrode body 25A are slightly inclined with respect to the Y-axis direction and extend along the inclined portion of the source line 27. The pixel electrode body 25A includes slits 25A1 that extend along the inclined portion of the source line 27 and are arranged at intervals with respect to the X-axis direction. The connection portion 25B extends from the pixel electrode body 25A toward the gate line 26 (downward in FIG. 4) connected to the TFT 24 that includes a target drain electrode 24C to be connected. The connection portion 25B extends along the Y-axis direction and has a vertically long rectangular plan view shape.

A detailed planar configuration of the TFT 24 will be described. As illustrated in FIG. 4, the gate electrode 24A of the TFT 24 is a portion of the gate line 26 that overlaps the semiconductor section 24D. The source electrode 24B is a portion of the source line 27 that overlaps the semiconductor section 24D and is connected to the semiconductor section 24D. The source line 27 includes a wide section and the wide section is configured as the source electrode 24B. The source electrode 24B is farther from the gate line 26 than the drain electrode 24C is in the Y-axis direction. The drain electrode 24C has a vertically long rectangular plan view shape and is in a middle between the two source lines 27 that are adjacent in the X-axis direction. The drain electrode 24C is disposed to overlap the connection portion 25B of the pixel electrode 25 in a plan view and connected to the connection portion 25B. The drain electrode 24C is connected to the semiconductor section 24D, which will be described later.

As illustrated in FIG. 4, the semiconductor section 24D extends from the source electrode 24B to the drain electrode 24C with being bent multiple times (three times). A first end of the semiconductor section 24D overlaps the source electrode 24B and is connected to the source electrode 24B and a second end of the semiconductor section 24D overlaps the drain electrode 24C and is connected to the drain electrode 24C. The semiconductor section 24D extends from the first end side along the Y-axis direction for a certain length with overlapping the source line 27 and is bent after crossing the gate line 26 and extends toward the drain electrode 24C (rightward in FIG. 4) along the X-axis direction. Then, the semiconductor section 24D is bent again and extends toward the drain electrode 24C (upward in FIG. 4) along the Y-axis direction and is bent again after crossing the gate line 26 and extends in an oblique direction with respect to the X-axis direction and the Y-axis direction to be away from the source electrode 24B and is connected to the drain electrode 24C. Thus, the middle portion of the semiconductor section 24D between the first end and the second end has a folded shape and crosses the gate line 26 twice. Therefore, the gate line 26 includes two overlapping portions overlapping one semiconductor section 24D. Namely, the gate line 26 includes two gate electrodes 24A. One TFT 24 includes two gate electrodes 24A.

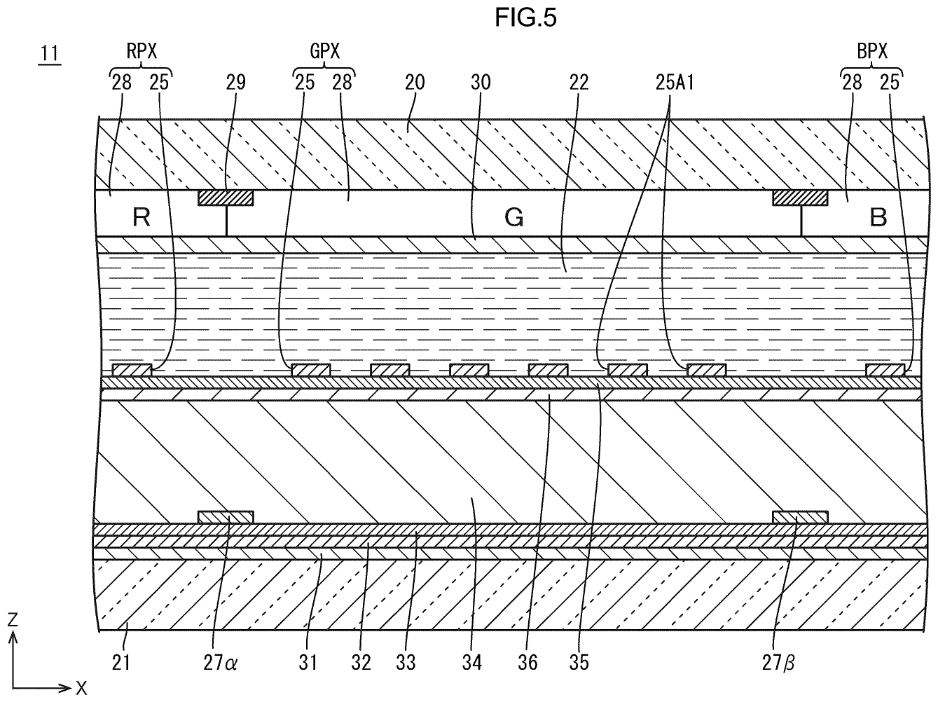

A configuration of the opposed substrate 20 of the liquid crystal panel 11 in the display area AA will be described with reference to FIG. 5. As illustrated in FIG. 5, color filters 28 are disposed in the display area AA of the opposed substrate 20 to overlap the pixel electrodes 25 of the array substrate 21, respectively. The color filters 28 that exhibit three different colors of red (R), green (G), and blue (B) are repeatedly arranged along the X-axis direction. The color filters 28 that exhibit three different colors extend along the Y-axis direction. Namely, the color filters 28 that exhibit different colors are arranged in a stripe as a whole. The color filter 28 and the corresponding pixel electrode 25 that are overlapped are configured as a pixel, which is a display unit. In the liquid crystal panel 11, the three color filters 28 that exhibit three different colors that are arranged along the X-axis direction and the three pixel electrodes 25 corresponding to the respective three color filters 28 are configured as the pixels GPX, BPX, RPX of three different colors. The pixels GPX, BPX, RPX of three colors include red pixels RPX exhibiting red, green pixels GPX exhibiting green, and blue pixels BPX exhibiting blue. In the liquid crystal panel 11, the pixels GPX, BPX, RPX of the three colors that are arranged adjacent to each other in the X-axis direction are configured as display pixels with which color display can be performed in predefined tones.

As illustrated in FIG. 5, in the display area AA of the opposed substrate 20, a black matrix 29 is disposed to define each of (on a boundary between) the pixels PX that are adjacent to each other in the X-axis direction and the Y-axis direction. The black matrix 29 is disposed in the display area AA and the non-display area NAA. The black matrix 29 is formed in a grid shape to overlap the gate lines 26 and the source lines 27 and is formed in substantially a solid pattern in the non-display area NAA. On an upper layer side of the color filters 28 and the black matrix 29, an overcoat film 30 is disposed. The overcoat film 30 is disposed in a solid manner on a substantially entire area of the opposed substrate 20. The overcoat film 30 is made of an organic material such as acrylic resin (PMMA) and disposed for planarization of an uneven surface on lower layer side. Alignment films for orienting the liquid crystal molecules in the liquid crystal layer 22 are formed on innermost surfaces (in an uppermost layer) of the substrates 20 and 21 in contact with the liquid crystal layer 22.

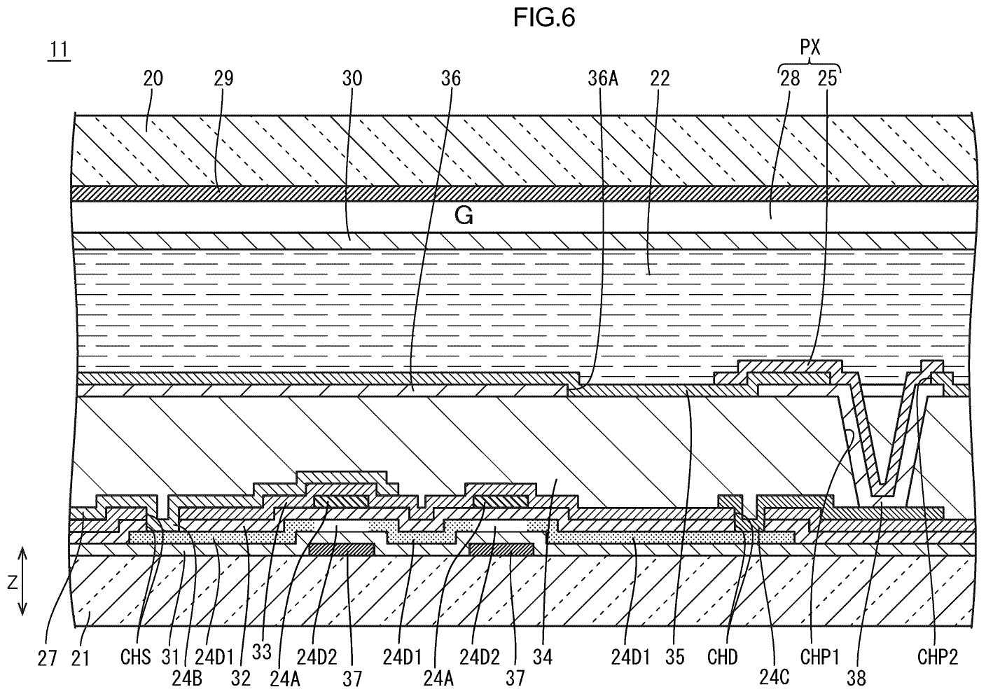

Films disposed on top of each other on the inner surface side of the array substrate 21 will be described with reference to FIG. 6. As illustrated in FIG. 6, in the array substrate 21, a first metal film (a light blocking film), a basecoat film 31, a semiconductor film, a gate insulating film 32, a second metal film (a first conductive film), a first interlayer insulating film 33 (a first insulating film), a third metal film (a second conductive film), a first planarization film 34, a first transparent electrode film, a second interlayer insulating film 35 (a second insulating film), a second transparent electrode film, and an alignment film are at least disposed on top of each other in this sequence from a lower layer side (from the glass substrate side).

The first metal film, the second metal film, and the third metal film may be a single-layer film made of one kind of metal, a multilayer film made of a material containing different kinds of metals, or an alloy. Examples of the metals include copper (Cu), titanium (Ti), aluminum (Al), molybdenum (Mo), and tungsten (W). With such a configuration, the first metal film, the second metal film, and the third metal film have electrically conductive properties and light blocking properties. The first metal film may be a single-layer film of molybdenum tungsten (MoW), for instance, and has a thickness of about 50 nm. A portion of the first metal film is configured as a light blocking portion 37. The second metal film may be a single-layer film of molybdenum tungsten (MoW), for instance, and has a thickness greater than that of the first metal film. The thickness of the second metal film may be about 400 nm. Portions of the second metal film are configured as portions of the gate lines 26 and the gate electrodes 24A of the TFTs 24. The third metal film may be a multilayer film including films of Ti/Al/Ti disposed on top of each other from a lower layer side. Thicknesses of the stacked films may be about 50 nm/300 nm/50 nm. Portions of the third metal film are configured as portions of the gate lines 26, the source lines 27, the source electrodes 24B and the drain electrodes 24C of the TFTs 24. The first transparent electrode film and the second transparent electrode film are made of a transparent electrode material (e.g., indium tin oxide (ITO) and indium zinc oxide (IZO)). A portion of the first transparent electrode film is configured as a common electrode 36. The first transparent electrode film may be made of ITO and have a thickness of about 50 nm. Portions of the second transparent electrode film are configured as the pixel electrodes 25. The second transparent electrode film may be made of ITO and have a thickness similar to that of the first transparent electrode film. The thickness of the second transparent electrode film may be about 50 nm.

The semiconductor film may be a continuous grain silicon (CG silicon) thin film that is one kind of polycrystalline silicon thin film. The CG silicon thin film is formed by adding a metal material to an amorphous silicon thin film and heating at a low temperature of 550° C. or lower for a short time. This process provides continuous atom arrangement at the grain boundaries of silicon crystal. Portions of the semiconductor film are configured as the semiconductor sections 24D of the TFTs 24.

The semiconductor film of this embodiment is subjected to a resistance lowering process in a producing process and the resistance is lowered in portions of the semiconductor film. Accordingly, the semiconductor section 24D includes a resistance lowered section 24D1. A portion of the semiconductor section 24D that is not subjected to the resistance lowering process is defined as a resistance non-lowered section 24D2. In FIG. 6, the resistance lowered section 24D1 of the semiconductor section 24D is illustrated with shading. Electrons can move through the resistance non-lowered section 24D2 of the semiconductor section 24D under a particular condition (when the scanning signals are supplied to the gate electrode 24A). Namely, the resistance non-lowered section 24D2 functions as a channel section under the particular condition. The resistance non-lowered section 24D2 overlaps the gate electrode 24A of the semiconductor section 24D in a plan view. The resistance lowered section 24D1 corresponds to the portion of the semiconductor section 24D that does not overlap the gate electrode 24A in a plan view. The resistivity of the resistance lowered section 24D1 is quite lower than that of the resistance non-lowered section 24D2 and is about 1/10,000,000,000 to 1/100 of the resistivity of the resistance non-lowered section 24D2. Electrons can always move through the resistance lowered section 24D1 and the resistance lowered section 24D1 functions as an electrically conductive member. In the process of producing the array substrate 21, after forming the gate lines 26 (including the gate electrodes 24A that are portions of the second metal film, the gate electrodes 24A are used as a mask when the semiconductor film is subjected to the resistance lowering process. In the resistance lowering process, the portions of the semiconductor film that are not covered by the gate electrodes 24A (non-overlapping portions, uncovered portions) are selectively subjected to the resistance lowering process and the portions of the semiconductor film that are covered by the gate electrodes 24A (overlapping portions, covered portions) are not subjected to the resistance lowering process. Examples of the resistance lowering process include a plasma surface treatment and an annealing treatment with using gas such as NH₃, H₂, N₂, He. The resistance lowered section 24D1 includes a first resistance lowered section 24D1 (a source section) that is connected to the source electrode 24B, a second resistance lowered section 24D1 (a drain section) that is connected to the drain electrode 24C, and a third resistance lowered section 24D1 that is connected to the two resistance non-lowered sections.

Each of the basecoat film 31, the gate insulating film 32, the first interlayer insulating film 33, and the second interlayer insulating film 35 is a single-layer film or a multilayer film made of inorganic material such as SiNₓ (silicon nitride) and SiO₂ (silicon dioxide, silicon oxide). As illustrated in FIG. 6, the basecoat film 31 is between the first metal film and the semiconductor s insulation between the light blocking portion 37 and the semiconductor section 24D. The basecoat film 31 is a base of the semiconductor film and prevents impurities from the glass substrate of the array substrate 21 from being dispersed toward the semiconductor film. The basecoat film 31 may be a multilayer film including a SiO₂ layer of about 200 nm thickness and a SiNₓ layer of about 20 nm thickness stacked from the lower layer side, for instance. The gate insulating film 32 is between the semiconductor film and the second metal film and keeps insulation between the gate electrode 24A and the semiconductor section 24D. The gate insulating film 32 is a single-layer film made of SiO₂ and has a thickness of about 130 nm. The first interlayer insulating film 33 is between the second metal film and the third metal film and keeps insulation between the gate line 26 and the source line 27 at the intersections of the gate line 26 and the source line 27. The first interlayer insulating film 33 is a multilayer film including a SiO₂ layer of about 470 nm thickness and a SiNₓ layer of about 280 nm thickness stacked from the lower layer side, for instance. The second interlayer insulating film 35 is between the first transparent electrode film and the second transparent electrode film and keeps insulation between the pixel electrode 25 and the common electrode 36. The gate insulating film 32 is a single-layer film made of SiNₓ and has a thickness of about 200 nm.

As illustrated in FIG. 6, the first planarization film 34 is between the third metal film and the first transparent electrode film and keeps insulation between the source line 27 and the common electrode 36. The first planarization film 34 is made of organic material such as PMMA (acrylic resin). The thickness of the first planarization film 34 is about 2.3 μm and is much greater than that of the basecoat film 31, the gate insulating film 32, the first interlayer insulating film 33, and the second interlayer insulating film 35. With the first planarization film 34, the inner surface of the array substrate 21 (a surface opposite the liquid crystal layer 22) is planarized.

The common electrode 36 will be described. The common electrode 36, which is a portion of the first transparent electrode film, has a size that is substantially same as that of the display area AA as a whole. As illustrated in FIG. 5, the common electrode 36 is disposed to overlap all the pixel electrodes 25 on a lower layer side of the pixel electrodes 25 via the second interlayer insulating film 35. The common electrode 36 is supplied with a common potential (a reference potential). The pixel electrode 25 is charged with a potential based on the image signal transmitted to the source line 27 when the TFT 24 is driven based on the scanning signal supplied via the gate line 26. Then, a potential difference occurs between the pixel electrode 25 and the common electrode 36. Then, a fringe electric field (an oblique electric field) is created between an opening edge of the slit 25A1 of the pixel electrode 25 and the common electrode 36. The fringe electric field includes a component parallel to the plate surface of the array substrate 21 and a component normal to the plate surface of the array substrate 21. With the fringe electric field, orientations of the liquid crystal molecules included in the liquid crystal layer 22 can be controlled. Based on the orientations of the liquid crystal molecules, predefined display is performed. Namely, the liquid crystal panel 11 according to this embodiment operates in the fringe field switching (FFS) mode.

Next, a cross-sectional configuration of the TFT 24 and relation of the TFT 24 and the films of the array substrate 21 will be described with reference to FIG. 6. As illustrated in FIG. 6, the TFTs 24 are top-gate type transistors and the gate electrode 24A is disposed above and overlaps the resistance non-lowered section 24D2 of the semiconductor section 24D via the gate insulating film 32. As illustrated in FIG. 6, the array substrate 21 includes the light blocking portion 37 that is a portion of the first metal film and overlaps the resistance non-lowered section 24D2 of the semiconductor section 24D. With the light blocking portion 37 being in a layer lower than (below) the resistance non-lowered section 24D2 of the semiconductor section 24D, the light blocking portion 37 can block light that is supplied from the backlight unit to the resistance non-lowered section 24D2 of the semiconductor section 24D from the lower layer side. The transistor characteristics of the TFTs 24 may be changed when the resistance non-lowered section 24D2 of the semiconductor section 24D is supplied with light; however, the light blocking portion 37 suppresses the change of the transistor characteristics of the TFTs 24. The light blocking portion 37 has a rectangular plan view shape. Two light blocking portions 37 are disposed to be away from each other in the X-axis direction and overlap two resistance non-lowered sections 24D2 of the semiconductor section 24D, respectively.

As illustrated in FIG. 6, the first interlayer insulating film 33, which is disposed between the first end of the semiconductor section 24D and the source electrode 24B of the TFT 24, includes a source contact hole CHS in a portion overlapping the first end of the semiconductor section 24D and the source electrode 24B. The first end of the semiconductor section 24D is connected to the source electrode 24B via the source contact hole CHS of the first interlayer insulating film 33. The first interlayer insulating film 33, which is disposed between the second end of the semiconductor section 24D and the drain electrode 24C of the TFT 24, includes a drain contact hole CHD in a portion overlapping the second end of the semiconductor section 24D and the drain electrode 24C. The second end of the semiconductor section 24D is connected to the drain electrode 24C via the drain contact hole CHD of the first interlayer insulating film 33. The drain contact hole CHD is away from a center of the drain electrode 24C in a plan view and closer to the source electrode 24B (the left side in FIG. 4) in the X-axis direction and closer to the pixel electrode body 25A (the upper side in FIG. 4) in the Y-axis direction.

As illustrated in FIGS. 4 and 6, an intermediate electrode 38, which is a portion of the first transparent electrode film, is disposed to overlap the drain electrode 24C of the TFT 24 and the connection portion 25B of the pixel electrode 25. The intermediate electrode 38 is in a middle between the drain electrode 24C and the pixel electrode 25 in the Z-axis direction. The intermediate electrode 38 has a square plan view shape and has an X-axis dimension that is almost same as that of the drain electrode 24C and has a Y-axis dimension that is smaller than that of the drain electrode 24C. The first planarization film 34, which is between the drain electrode 24C and the intermediate electrode 38, includes a first pixel contact hole CHP1 in a portion overlapping the drain electrode 24C and the intermediate electrode 38. The intermediate electrode 38 is connected to the drain electrode 24C via the first pixel contact hole CHP1. The second interlayer insulating film 35, which is between the intermediate electrode 38 and the connection portion 25B of the pixel electrode 25, includes a second pixel contact hole CHP2 in a portion overlapping the intermediate electrode 38 and the connection portion 25B of the pixel electrode 25. The connection portion 25B of the pixel electrode 25 is connected to the intermediate electrode 38 via the second pixel contact hole CHP2. Thus, the pixel electrode 25 is connected to the drain electrode 24C via the intermediate electrode 38.

As illustrated in FIGS. 4 and 6, the intermediate electrode 38 has an island shape and is physically separated from the common electrode 36 that is a portion of the first transparent electrode film another portion of which is configured as the intermediate electrode 38. Specifically, the common electrode 36 includes an opening 36A that surrounds the intermediate electrode 38. The opening 36A has a substantially rectangular frame plan view shape. The opening 36A includes a first slit 36A1 that extends toward one side (toward a right side in FIG. 4) along the X-axis direction and a second slit 36A2 that extends toward other side (toward a left side in FIG. 4) along the X-axis direction. With the opening 36A having such a configuration, a short circuit is less likely to occur between the common electrode 36 and the intermediate electrode 38 and local charge up is less likely to be caused. The local charge up is caused by concentration of the electric field between the common electrode 36 and the pixel electrode 25 when the pixel electrode 25 is charged for a long time.

Among the three source lines 27 arranged along the X-axis direction as illustrated in FIG. 4, one in a middle in the FIG. 4 is defined as a first source line 27α (a second line), another one on a right end in FIG. 4 is defined as a second source line 27β (a third line), and the other one on a left end in FIG. 4 is defined as a third source line 27γ (a fourth line). Between the two pixel electrodes 25 arranged along the X-axis direction, one that is between the first source line 27α and the third source line 27γ in the X-axis direction is defined as a first pixel electrode 25α and the other one that is between the first source line 27α and the second source line 27β in the X-axis direction is defined as a second pixel electrode 25β. The pixel electrode body 25A of the first pixel electrode 25α is defined as a first pixel electrode body 25Aα and the connection portion 25B of the first pixel electrode 25α is defined as a first connection portion 25βα. Between the two TFTs 24 arranged along the X-axis direction, one connected to the first pixel electrode 25α is defined as a first TFT 24α (a first switching component) and the other one connected to the second pixel electrode 25β is defined as a second TFT 24β (a second switching component). The gate electrode 24A of the first TFT 24α is defined as a first gate electrode 24Aα (a second electrode), the source electrode 24B of the first TFT 24α is defined as a first source electrode 24Bα (a sixth electrode), and the drain electrode 24C of the first TFT 24α is defined as a first drain electrode 24Cα (a first electrode). The semiconductor section 24D of the first TFT 24α is defined as a first semiconductor section 24Dα. The gate electrode 24A of the second TFT 24β is defined as a second gate electrode 24Aβ (a fourth electrode), the source electrode 24B of the second TFT 24β is defined as a second source electrode 24Bβ, and the drain electrode 24C of the second TFT 24β is defined as a second drain electrode 24Cβ (a third electrode). The semiconductor section of the second TFT 24β is defined as a second semiconductor section 24Dβ.

As illustrated in FIG. 4, the first TFT 24α and the second TFT 24β are driven based on the scan signals supplied to the first gate electrode 24Aα and the second gate electrode 24Aβ, respectively. The image signal supplied to the third source line 27γ from the driver 12 is supplied to the first drain electrode 24Cα via the first semiconductor section 24Dα from the first source electrode 24Bα, and the first pixel electrode 25α is charged at a potential related to the supplied image signal. The image signal supplied to the second source line 27β from the driver 12 is supplied to the second drain electrode 24Cβ via the second semiconductor section 24Dβ from the second source electrode 24Bβ, and the second pixel electrode 25ß is charged at a potential related to the supplied image signal.

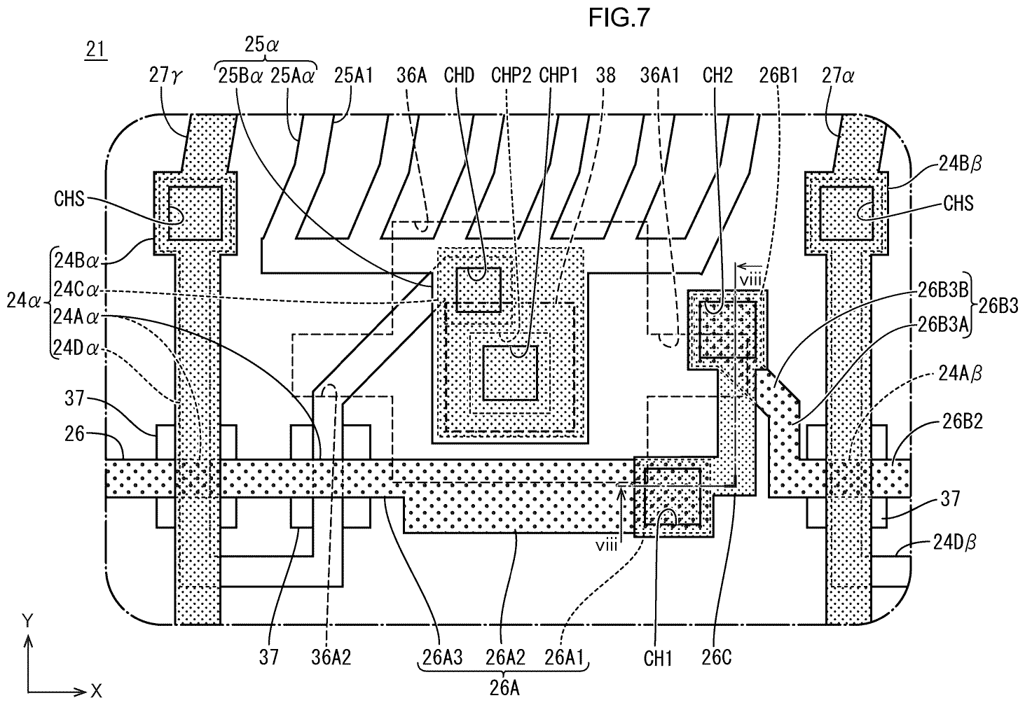

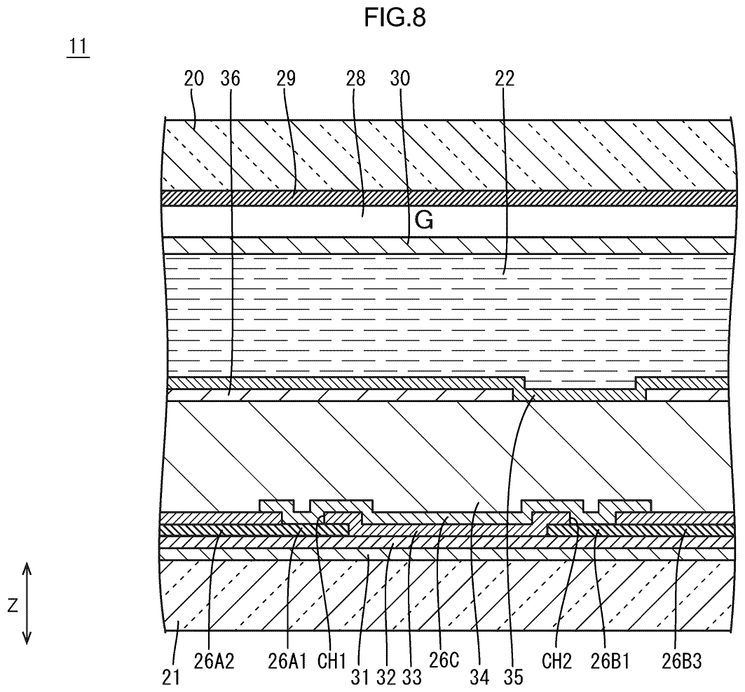

As illustrated in FIGS. 7 and 8, the gate line 26 has a separated structure and at least includes a first line section 26A, a second line section 26B, and a first connection electrode 26C. In FIG. 7, the structure of the second metal film and the structure of the third metal film are illustrated with different types of shadings. Each of the first line section 26A and the second line section 26B is a portion of the second metal film and extends along the X-axis direction. The first connection electrode 26C is a portion of the third metal film and extends along the Y-axis direction and connected to the first line section 26A and the second line section 26B.

As illustrated in FIG. 7, the first line section 26A is disposed adjacent to and on the left side of the second line section 26B and the second line section 26B is disposed adjacent to and on the right side of the first line section 26A. A border between the first line section 26A and the second line section 26B is between the first source line 27α and the third source line 27γ with respect to the X-axis direction and specifically is between the first drain electrode 24Cα and the first source line 27α. The first line section 26A has two end portions with respect to the X-axis direction. One of the two end portions on the second line section 26B side (on the right side in FIG. 7) is defined as a first end portion 26A1. The first end portion 26A1 is disposed between the first drain electrode 24Cα (the first connection portion 25Bα and the intermediate electrode 38) and the first source line 27α. More in detail, the first end portion 26A1 is closer to the first drain electrode 24Cα than the first source line 27α with respect to the X-axis direction. The second line section 26B has two end portions with respect to the X-axis direction. One of the two end portions on the first line section 26A side (on the left side in FIG. 7) is defined as a second end portion 26B1. The second end portion 26B1 is disposed between the first drain electrode 24Cα and the first source line 27α. More in detail, the second end portion 26B1 is closer to the first source line 27α than the first drain electrode 24Cα with respect to the X-axis direction. The second end portion 26B1 is disposed on the same side (on the upper side in FIG. 7) as the first drain electrode 24Cα with respect to the first end portion 26A1 (the first line section 26A) in the Y-axis direction. The second end portion 26B1 is spaced from the first end portion 26A1 with respect to the Y-axis direction. More in detail, the second end portion 26B1 is disposed between the first end portion 26A1 and the first pixel electrode body 25Aα of the first pixel electrode 25α in the Y-axis direction. The second end portion 26B1 is closer to the first pixel electrode body 25Aα in the Y-axis direction than the first end portion 26A1 is.

As illustrated in FIGS. 7 and 8, a first end portion of the first connection electrode 26C overlaps the first end portion 26A1 of the first line section 26A and a second end portion of the first connection electrode 26C overlaps the second end portion 26B1 of the second line section 26B. The first connection electrode 26C extends substantially along the Y-axis direction so as to extend from the first end portion 26A1 of the first line section 26A to the second end portion 26B1 of the second line section 26B. More in detail, the first connection electrode 26C extends from the first end portion 26A1 toward the first source line 27α along the X-axis direction and is bent upwardly and extends to the second end portion 26B1 along the Y-axis direction. The first interlayer insulating film 33 includes a first contact hole CH1 in a portion overlapping the first end portion 26A1 of the first line section 26A and the first end portion of the first connection electrode 26C and a second contact hole CH2 in a portion overlapping the second end portion 26B1 of the second line section 26B and the second end portion of the first connection electrode 26C.

With the gate line 26 having such a configuration, operations and advantageous effects described below are obtained. In a process of producing the array substrate 21, with the second metal film being formed and patterned, the first line section 26A and the second line section 26B of the gate line 26 are formed. At this time, the first line section 26A and the second line section 26B are not connected and therefore, electrostatic discharge is less likely to be caused in the first line section 26A and the second line section 26B due to separation charge compared to a configuration in which the first line section and the second line section are connected. With the first interlayer insulating film 33 being formed and patterned after patterning the second metal film, the first contact hole CH1 is formed in a portion of the first interlayer insulating film 33 overlapping the first end portion 26A1 of the first line section 26A and the second contact hole CH2 is formed in a portion of the first interlayer insulating film 33 overlapping the second end portion 26B1 of the second line section 26B. Then, with the third metal film being formed and patterned, the first source line 27α, the first drain electrode 24Cα, and the first connection electrode 26C are formed. As illustrated in FIG. 8, the first connection electrode 26C is connected to the first end portion 26A1 of the first line section 26A via the first contact hole CH1 and is connected to the second end portion 26B1 of the second line section 26B via the second contact hole CH2. The first line section 26A, the second line section 26B, and the first connection electrode 26C are connected to each other and configured as the gate line 26.

As illustrated in FIGS. 7 and 8, the first connection electrode 26C extends from the first end portion 26A1 to the second end portion 26B1 of the second line section 26B. The second end portion 26B1 is disposed on the same side as the first drain electrode 24Cα with respect to the first end portion 26A1 in the Y-axis direction and the second end portion 26B1 is spaced from the first end portion 26A1 with respect to the Y-axis direction. Furthermore, the second end portion 26B1 is disposed between the first source line 27α and the first drain electrode 24Cα in the X-axis direction. With such a configuration, the space between the first drain electrode 24Cα and the first source line 27α in the X-axis direction can be reduced with keeping enough space between the first connection electrode 26C and the first drain electrode 24Cα in the X-axis direction and enough space between the first connection electrode 26C and the first source line 27α in the X-axis direction. Accordingly, high resolution is preferably achieved.

As previously described, as illustrated in FIG. 7, the second end portion 26B1 that overlaps the second end portion of the first connection electrode 26C is between the first end portion 26A1 and the first pixel electrode body 25Aα of the first pixel electrode 25α in the Y-axis direction. Namely, the first connection electrode 26C is disposed between the first end portion 26A1 and the first pixel electrode body 25Aα in the Y-axis direction. Thus, with the first connection electrode 26C being disposed not to overlap the first pixel electrode 25α in the Z-axis direction, a parasitic capacitance that may be caused between the gate line 26 and the first pixel electrode 25α can be reduced.

In this embodiment, as illustrated in FIG. 7, the first end portion 26A1 and the second end portion 26B1 partially overlap with respect to the Y-axis direction. More in detail, the first source line 27α side end portion of the first end portion 26A1 in the X-axis direction overlaps the first drain electrode 24Cα side end portion of the second end portion 26B1 in the X-axis direction. With such a configuration, the space extending in the X-axis direction and necessary for arranging the first connection electrode 26C, which extends from the first end portion 26A1 to the second end portion 26B1, can be reduced compared to an arrangement in which the first end portion and the second end portion do not overlap with respect to the Y-axis direction. This can reduce the space between the first drain electrode 24Cα and the first source line 27α and high resolution can be preferably achieved.

As illustrated in FIG. 7, the first line section 26A of this embodiment extends straight along the X-axis direction and a width of the first line section 26A changes. The first line section 26A at least includes a wide section 26A2 and a narrow section 26A3 that is narrower than the wide section 26A2. The wide section 26A2 includes the first end portion 26A1 that is disposed next to and spaced from the first drain electrode 24Cα in the Y-axis direction and on an opposite end side from the narrow section 26A3 in the X-axis direction. The wide section 26A2 protrudes (downward in FIG. 7) away from the first drain electrode 24Cα in the Y-axis direction (the line width direction). The wide section 26A2 protrudes further from a side edge of the narrow section 26A3 in the Y-axis direction. The first line section 26A has two side edges. One of the two side edges on an opposite side from the first drain electrode 24Cα in the Y-axis direction has bent portions and the other one of two side edges on the first drain electrode 24Cα side (the upper one in FIG. 7) in the Y-axis direction is straight. The narrow section 26A3 is on an opposite side from the second line section 26B with respect to the wide section 26A2 in the X-axis direction. The narrow section 26A3 crosses the third source line 27γ and the first semiconductor section 24Dα.

As illustrated in FIGS. 4 and 7, the second line section 26B includes a body section 26B2 that extends straight similar to the first line section 26A and a bent section 26B3 that extends from the body section 26B2 to the second end portion 26B1 with being bent. More in detail, the body section 26B2 extends straight along the X-axis direction and a width of the body section 26B2 changes similar to the first line section 26A. The body section 26B2 at least includes a wide section 26B2A and two narrow sections 26B2B that are narrower than the wide section 26B2A. The wide section 26B2A is disposed next to and spaced from the second drain electrode 24Cβ in the Y-axis direction. The wide section 26B2A protrudes (downward in FIGS. 4 and 7) away from the first drain electrode 24Cβ in the Y-axis direction (the line width direction). The wide section 26B2A protrudes further from a side edge of the narrow section 26B2B in the Y-axis direction. The body section 26B2 has two side edges. One of the two side edges on an opposite side from the second drain electrode 24Cβ in the Y-axis direction has bent portions and the other one of two side edges on the second drain electrode 24Cβ side (the upper one in FIGS. 4 and 7) in the Y-axis direction is straight and extends on the same straight line as the other one of two side edges of the first line section 26A on the first drain electrode 24Cα side (the upper one in FIG. 7). Thus, the first line section 26A and the body section 26B2 of the second line section 26B extend along the X-axis direction and are on the same straight line. With such a configuration, the gate line 26 has less influences on the arrangement of other structures (such as the TFTs 24 and the pixel electrodes 25) compared to a configuration in which the first line section and the body section are not disposed on the same straight line (are disposed on different lines).

As illustrated in FIGS. 4 and 7, one of the two narrow sections 26B2B of the second line section 26B is disposed on the first line section 26A side with respect to the body section 26B2 in the X-axis direction and crosses the first source line 27α and the second semiconductor section 24Dβ. The other one of the two narrow sections 26B2B is disposed on an opposite side from the first line section 26A with respect to the body section 26B2 in the X-axis direction and crosses the second source line 27β. Thus, the second line section 26B crosses each of the first source line 27α and the second source line 27β via the first interlayer insulating film 33. Namely, the second line section 26B has a non-separated structure at least between the first source line 27α and the second source line 27β in the X-axis direction. Therefore, in this embodiment, a connection structure for connecting the separated sections is not necessary unlike the configuration in which the second line section is separated between the first source line 27α and the second source line 27β and the separated sections are connected by a connection electrode. This preferably improves production yield.

As illustrated in FIG. 7, the bent section 26B3 has a same width as the width of the narrow section 26B2B of the body section 26B2. The bent section 26B3 extends substantially along the Y-axis direction and extends from the first end portion 26A1 side end of the body section 26B2 to the second end portion 26B1. More in detail, the bent section 26B3 includes a first bent portion 26B3A and a second bent portion 26B3B. The first bent portion 26B3A extends from the first end portion 26A1 side end of the body section 26B2 along the Y-axis direction toward the second end portion 26B1 side (upward in FIG. 7). The second bent portion 26B3B extends from an end of the first bent portion 26B3A along an oblique direction that is oblique with respect to the X-axis direction and the Y-axis direction. The first bent portion 26B3A extends parallel to the first connection electrode 26C and is disposed slightly away from the first connection electrode 26C in the X-axis direction. The second bent portion 26B3B crosses the first connection electrode 26C and is continuous to the second end portion 26B1. The second end portion 26B1 is wider than the bent section 26B3 and has a substantially same width dimension as the wide section 26B2A of the body section 26B2. The two end portions of the first connection electrode 26C overlapping the first end portion 26A1 and the second end portion 26B1, respectively, are wider than a middle portion of the first connection electrode 26C. The middle portion of the first connection electrode 26C that is continuous to the two end portions have substantially same width as the narrow sections 26A3, 26B2. The bent section 26B3 is between the first connection electrode 26C and the first source line 27α in the X-axis direction. With such a configuration, enough space can be provided between the first end portion 26A1 and the bent section 26B3 in the X-axis direction. Accordingly, in the process of producing the array substrate 21, when the second metal film is formed and patterned, short circuit is less likely to be caused between the first line section 26A and the second line section 26B. Electrostatic discharge can be suppressed with high reliability.

As previously described, the array substrate 21 of this embodiment includes a gate line 26 (a first line) extending along the first direction, the first source line 27α (the second line) extending along the second direction that crosses the first direction, the first drain electrode 24Cα (the first electrode), and the first interlayer insulating film 33 (the first insulating film). The first drain electrode 24Cα is spaced from the gate line 26 in the second direction and is spaced from the first source line 27α in the first direction. The gate line 26 includes the first line section 26A, the second line section 26B, and the first connection electrode 26C. The first line section 26A is a portion of the second metal film (the first conductive film) that is in a layer lower than the first interlayer insulating film 33. The second line section 26B is a portion of the second metal film that is different from the portion of the second metal film configured as the first line section 26A. The first connection electrode 26C is a portion of the third metal film (the second conductive film) that is in a layer upper than the first interlayer insulating film 33. The first source line 27α is a portion of the third metal film that is different from the portion of the third metal film configured as the first connection electrode 26C. The first drain electrode 24Cα is a portion of the third metal film that is different from the portions of the third metal film configured as the first connection electrode 26C and the first source line 27α. The first line section 26A includes the first end portion 26A1. The second line section 26B includes the second end portion 26B1. The second end portion 26B1 is away from the first end portion 26A1 in the second direction and on the same side as the first drain electrode 24Cα in the second direction. The second end portion 26B1 is between the first source line 27α and the first drain electrode 24Cα in the first direction. The first connection electrode 26C extends from the first end portion 26A1 to the second end portion 26B1. The first interlayer insulating film includes the first contact hole CH1 in a portion overlapping the first end portion 26A1 and the first connection electrode 26C and the second contact hole CH2 in a portion overlapping the second end portion 26B1 and the first connection electrode 26C.

In the process of producing the array substrate 21, with the second metal film being formed and patterned, the first line section 26A and the second line section 26B of the gate line 26 are formed. At this time, the first line section 26A and the second line section 26B are not connected and therefore, electrostatic discharge is less likely to be caused in the first line section 26A and the second line section 26B due to separation charge compared to a configuration in which the first line section and the second line section are connected. With the first interlayer insulating film 33 being formed and patterned after patterning the second metal film, the first contact hole CH1 is formed in a portion of the first interlayer insulating film 33 overlapping the first end portion 26A1 of the first line section 26A and the second contact hole CH2 is formed in a portion of the first interlayer insulating film 33 overlapping the second end portion 26B1 of the second line section 26B. Then, with the third metal film being formed and patterned, the first source line 27α, the first drain electrode 24Cα, and the first connection electrode 26C are formed. The first connection electrode 26C is connected to the first end portion 26A1 of the first line section 26A via the first contact hole CH1 and is connected to the second end portion 26B1 of the second line section 26B via the second contact hole CH2. The first line section 26A, the second line section 26B, and the first connection electrode 26C are connected to each other and configured as the gate line 26.

The first connection electrode 26C extends from the first end portion 26A1 to the second end portion 26B1 of the second line section 26B. The second end portion 26B1 is disposed on the same side as the first drain electrode 24Cα with respect to first end portion 26A1 in the second direction and the second end portion 26B1 is spaced from the first end portion 26A1 with respect to the second direction. Furthermore, the second end portion 26B1 is disposed between the first source line 27α and the first drain electrode 24Cα in the first direction. With such a configuration, the space between the first drain electrode 24Cα and the first source line 27α can be reduced with keeping enough space between the first connection electrode 26C and the first drain electrode 24Cα and enough space between the first connection electrode 26C and the first source line 27α. Accordingly, high resolution is preferably achieved.

The first line section 26A extends along the first direction. The second line section 26B includes the body section 26B2 and the bent section 26B3. The body section 26B2 extends along the first direction and extends on the same straight line as the first line section 26A extends. The bent section 26B3 extends from the body section 26B2 with being bent to the second end portion 26B1. The first line section 26A and the body section 26B2 of the second line section 26B extend along the first direction and are on the same straight line. With such a configuration, the gate line 26 has less influence on the arrangement of other structures. The bent section 26B3 extending with being bent from the body section 26B2 is continuous to the second end portion 26B1 and thus, the body section 26B2 and the second end portion 26B1 are connected.

The bent section 26B3 is between the first connection electrode 26C and the first source line 27α in the first direction. With such a configuration, enough space can be provided between the first end portion 26A1 and the bent section 26B3 in the first direction. Accordingly, in the process of producing the array substrate 21, when the second metal film is formed and patterned, short circuit is less likely to be caused between the first line section 26A and the second line section 26B. Therefore, electrostatic discharge can be suppressed with high reliability.

The first end portion 26A1 and the second end portion 26B1 are disposed to overlap with respect to the second direction. With such a configuration, the space extending in the first direction and necessary for arranging the first connection electrode 26C, which extends from the first end portion 26A1 to the second end portion 26B1, can be reduced compared to an arrangement in which the first end portion and the second end portion do not overlap with respect to the second direction. This can reduce the space between the first drain electrode 24Cα and the first source line 27α and high resolution can be preferably achieved.

The array substrate 21 of this embodiment includes the first TFT 24α (the first switching component) including the first drain electrode 24Cα and the first pixel electrode 25α that is connected to the first drain electrode 24Cα. The first TFT 24α includes the first gate electrode 24Aα (the second electrode) that is a portion of the first line section 26A. The first pixel electrode 25α includes the first connection portion 25Bα that is connected to the first drain electrode 24Cα and the first pixel electrode body 25Aα that is disposed on an opposite side from the gate line 26 with respect to the first connection portion 25Bα in the second direction. The first connection electrode 26C is disposed between the first line section 26A and the first pixel electrode body 25Aα with respect to the second direction. The first TFT 24α is driven based on the signal supplied to the first gate electrode 24Aα via the gate line 26 and a potential is supplied from the first drain electrode 24Cα to the first pixel electrode 25α. The first connection electrode 26C is disposed between the first line section 26A and the first pixel electrode body 25Aα and not to overlap the first pixel electrode 25α. With such a configuration, a parasitic capacitance that may be caused between the gate line 26 and the first pixel electrode 25α can be reduced.

The array substrate 21 of this embodiment may include the first TFT 24α including the first drain electrode 24Cα, the first pixel electrode 25α that is connected to the first drain electrode 24Cα, the second source line 27β (the third line), the second drain electrode 24Cβ (the third electrode), the second TFT 24β (the second switching component) including the second drain electrode 24Cβ, and the second pixel electrode 25β that is connected to the second drain electrode 24Cβ. The second source line 27β extends along the second direction and is disposed on an opposite side from the first drain electrode 24Cα with respect to the first source line 27α in the first direction and spaced from the first source line 27α. The second drain electrode 24Cβ is disposed on the same side as the first drain electrode 24Cα with respect to the gate line 26 in the second direction and the second drain electrode 24Cβ is spaced from the gate line 26 with respect to the second direction. The second drain electrode 24Cβ is disposed between the first source line 27α and the second source line 27β in the first direction. The first TFT 24α includes the first gate electrode 24Aα that is a portion of the first line section 26A. The second TFT 24β includes the second gate electrode 24Aβ (the fourth electrode) that is a portion of the second line section 26B. The second source line 27β is a portion of the third metal film that is different from the portions of the third metal film configured as the first connection electrode 26C, the first source line 27α, and the first drain electrode 24Cα. The second drain electrode 24Cβ is a portion of the third metal film that is different from the portions of the third metal film configured as the first connection electrode 26C, the first source line 27α, the first drain electrode 24Cα and the second source line 27β. The second line section 26B crosses each of the first source line 27α and the second source line 27β via the first interlayer insulating film 33. The first TFT 24α is driven based on the signal supplied to the first gate electrode 24Aα via the gate line 26 and a potential is supplied from the first drain electrode 24Cα to the first pixel electrode 25α. The second TFT 24β is driven based on the signal supplied to the second gate electrode 24Aβ via the gate line 26 and a potential is supplied from the second drain electrode 24Cβ to the second pixel electrode 25β. The second line section 26B crosses each of the first source line 27α and the second source line 27β via the first interlayer insulating film 33. Namely, the second line section 26B has a non-separated structure at least between the first source line 27α and the second source line 27β in the first direction. Therefore, a connection structure for connecting the separated sections is not necessary unlike the configuration in which the second line section is separated between the first source line 27α and the second source line 27β and the separated sections are connected by a connection electrode. This preferably improves production yield.

The liquid crystal panel 11 (the display device) of this embodiment includes the array substrate 21 and the opposed substrate 20 that is disposed to be opposite and away from the array substrate 21. According to the liquid crystal panel 11 having such a configuration, high resolution can be preferably achieved.

### Second Embodiment

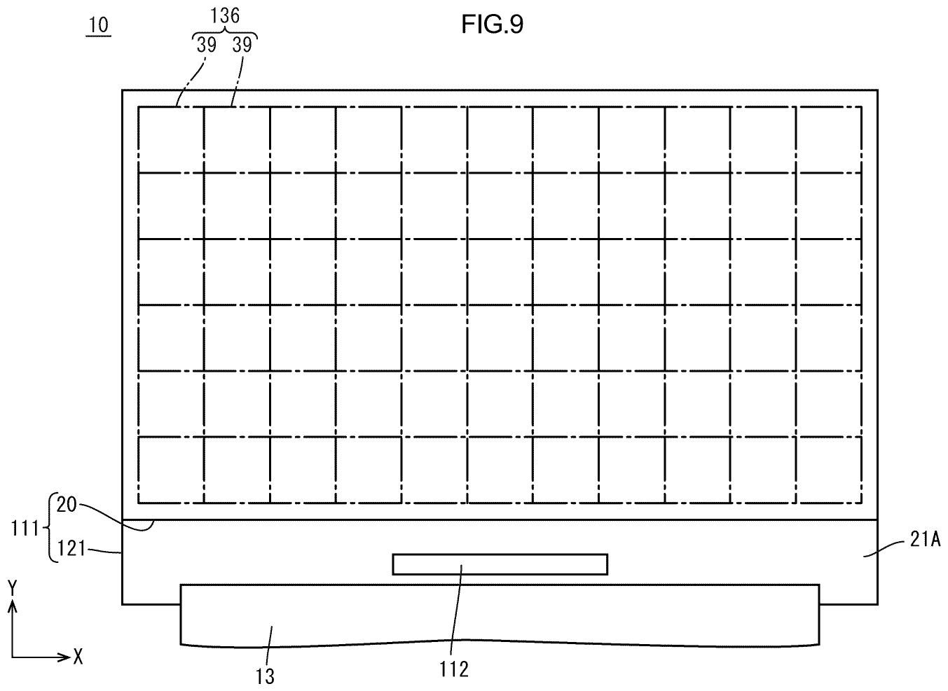

A second embodiment will be described with reference to FIGS. 9 to 11. The second embodiment additionally includes a touch panel function. Configuration, operations, and effects similar to those of the first embodiment may not be described.

As illustrated in FIG. 9, a liquid crystal panel 111 according to this embodiment has a display function for displaying images and a touch panel function for detecting positions of input performed by a user based on the displayed images (input positions). The liquid crystal panel 111 includes an integrated touch panel pattern (with an in-cell technology) for exerting the touch panel function. The touch panel pattern uses so-called a projection type electrostatic capacitance method. A self-capacitance method is used for detection. The touch panel pattern includes touch electrodes 39 (a position detection electrode) that are arranged in a matrix within a plate surface of the liquid crystal panel 111. The touch electrodes 39 are disposed in the display area AA of the liquid crystal panel 111. The display area AA of the liquid crystal panel 111 substantially corresponds to a touch area in which input positions are detectable (a position input area). The non-display area NAA substantially corresponds to a non-touch area in which input positions are not detectable (a non-position input area). When the user intends to input a position based on a displayed image that is displayed in the display area AA of the liquid crystal panel 111 and the user moves a finger (a position input body) that is an electrically conductive member closer to the surface of the liquid crystal panel 111, the finger and the touch electrode 39 form a capacitor. A capacitance measured at the touch electrode 39 close to the finger changes as the finger approaches the touch electrode 39 and is different from a capacitance at the touch electrodes 39 farther from the finger. Based on the difference in capacitance, the input position can be detected.

As illustrated in FIG. 9, the touch electrodes 39 are divided sections of a common electrode 136. The common electrode 136 includes dividing slits that are formed in a grid in a plan view. The common electrode 136 is divided into the touch electrodes 39 with a grid pattern in a plan view by the dividing slits and includes the touch electrodes 39 that are electrically independent from one another. The touch electrodes 39 that are arranged in a grid are separated by the dividing slits. The number of the touch electrodes 39 may be altered as appropriate from that illustrated in FIG. 6. The touch electrode 39 has a substantially square plan view shape and one side dimension is about several millimeters. The plan view size of the touch electrode 39 is much larger than that of a pixel PX. The touch electrode 39 extends to overlap the pixels PX both in the X-axis direction and the Y-axis direction.

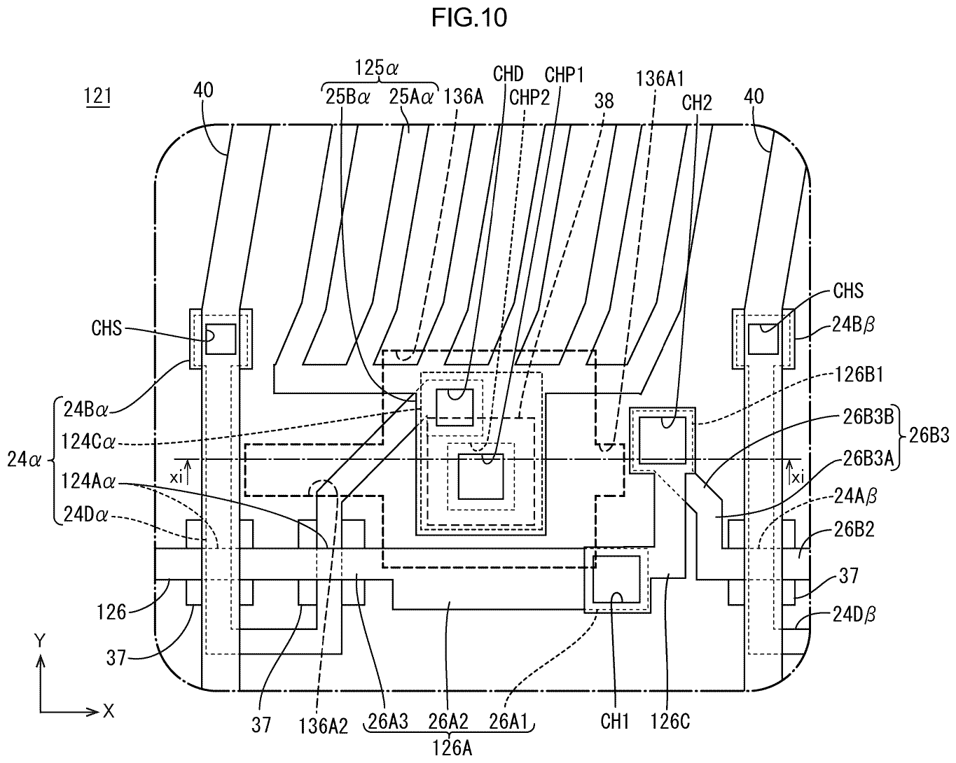

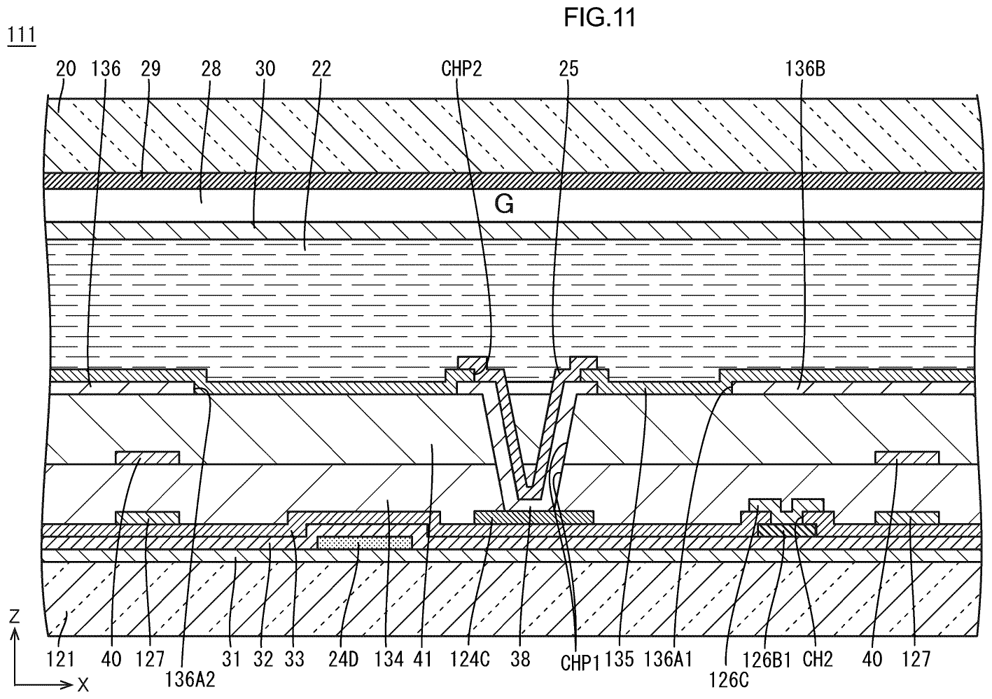

As illustrated in FIGS. 10 and 11, touch lines 40 (a position detection line) that are to be connected to the touch electrodes 39, respectively, are disposed on an inner surface side of an array substrate 121 in the display area AA. The touch lines 40 extend along the Y-axis direction and parallel to source lines 127. The touch lines 40 are disposed to overlap the source lines 127, respectively, in a plan view. The touch lines 40 are connected to the touch electrodes 39, respectively. Ends of the touch lines 40 that are opposite ends from the ends to be connected to the respective touch electrodes 39 are connected to a driver 112 (refer to FIG. 9). The touch lines 40 are supplied with common signals (a reference potential signal) for the image display function and touch signals (a position detection signal) for the touch function from the driver 112 at different timing. A period while the touch lines 40 are supplied with the common signals from the driver 112 is a display period and a period while the touch lines 40 are supplied with the touch signals from the driver 112 is a sensing period (a position detection period). The common signals are transmitted to all the touch lines 40 in the display period and thus all the touch electrodes 39 are charged at the reference potential and function as the common electrode 136.

As illustrated in FIG. 11, a fourth metal film is disposed in a layer upper than a first planarization film 134 and a second planarization film 41 is disposed in a layer upper than the fourth metal film and lower than the first transparent electrode film. Portions of the fourth metal film are configured as the touch lines 40. The fourth metal film may have a same configuration as that of the third metal film. Specifically, the fourth metal film may be a multilayer film including films of Ti/Al/Ti disposed on top of each other from a lower layer side. Thicknesses of the stacked films may be about 50 nm/300 nm/50 nm. Similar to the first planarization film 34, the second planarization film 41 may be made of an organic material such as PMMA (acrylic resin) and have a thickness of about 2.3 μm. The second planarization film 41 is disposed between the third metal film and the first transparent electrode film and keeps insulation between the touch lines 40 and the common electrode 136 (the touch electrodes 39). The second planarization film 41 includes a contact hole in a portion overlapping the touch line 40 and the target touch electrode 39 to be connected to the touch line 40. The touch line 40 and the target touch electrode 39 are connected via the contact hole.

As illustrated in FIG. 10, the common electrode 136 of this embodiment includes openings 136A. The openings 136A include first slits 136A1 and second slits 136A2 that are longer in the X-axis direction than the first slits 136A1. More in detail, the first slit 136A1 is shorter in the X-axis direction than the first slit 36A1 of the first embodiment (refer to FIG. 7). The second slit 136A2 is longer in the X-axis direction than the second slit 36A2 of the first embodiment (refer to FIG. 7). A total of the X-axis lengths of the first slit 136A1 and the second slit 136A2 is substantially equal to a total of the X-axis lengths of the first slit 36A1 and the second slit 36A2 of the first embodiment. Therefore, the opening 136A of this embodiment has an opening area that is substantially equal to the opening area of the opening 36A of the first embodiment (refer to FIG. 7) and a sufficient opening area is obtained in this embodiment. The first slit 136A1 of one of the two openings 136A that are adjacent to each other in the X-axis direction and the second slit 136A2 of the other one of the two openings 136A are connected. The connected first slit 136A1 and the second slit 136A2 are configured as the dividing slit that defines each of two touch electrodes 39 that are adjacent to in the Y-axis direction. Therefore, the opening area of the opening 136A that is configured as a portion of the dividing slit differs from the opening area of the opening 136A that is not configured as a portion of the dividing slit. Due to the difference in the opening area, parasitic capacitances that may be caused between the lines near the openings 136A (such as the gate line 26 and the source line 127) and the touch electrodes 39 may be varied. In this respect, the opening 136A of this embodiment has an opening area that is substantially equal to that of the opening 36A of the first embodiment (refer to FIG. 7) and a sufficient opening area is obtained. Therefore, the difference in the parasitic capacitances is less likely to be caused and display unevenness is less likely to be recognized.

As illustrated in FIG. 10, the common electrode 136 is disposed such that the second slit 136A2 of the opening 136A does not overlap a second end portion 126B1 and a first connection electrode 126C. Namely, the second slit 136A2 extends in the X-axis direction from a body section of the opening 136A just before a second end portion 126B1 and the first connection electrode 126C. As illustrated in FIG. 11, the common electrode 136 includes an overlapping portion 136B that overlaps the second end portion 126B1 and another end portion of the first connection electrode 126C. With such a configuration, an electric field that may be created between the first connection electrode 126C and the first pixel electrode 125α is blocked by the overlapping portion 136B. Accordingly, a potential of the first pixel electrode 125α is preferably maintained.

The array substrate 121 of this embodiment includes a first TFT 124α including a first drain electrode 124Cα, a first pixel electrode 125α that is connected to the first drain electrode 124Cα, a second interlayer insulating film 135 (the second insulating film) that is disposed in a layer lower than the first pixel electrode 125α, and the common electrode 136 that is included in a layer lower than the second interlayer insulating film 135 to overlap the first pixel electrode 125α. The first TFT 124α includes a first gate electrode 124Aα that is a portion of the first line section 126A. The common electrode 136 includes the opening 136A that surrounds the first drain electrode 124Cα and the overlapping portion 136B that overlaps the first connection electrode 126C. The first TFT 124α is driven based on the signal supplied to the first gate electrode 124Aα via the gate line 126 and a potential is supplied from the first drain electrode 124Cα to the first pixel electrode 125α. An electric field is created between the charged first pixel electrode 125α and the common electrode 136 that overlaps the charged first pixel electrode 125α via the second interlayer insulating film 135. With an opening edge of the opening 136A of the common electrode 136 surrounding the first drain electrode 124Cα, a parasitic capacitance that may be caused between the line near the first drain electrode 124Cα (including the gate line 126 and the first source line 127α) and the common electrode 136 can be reduced. The common electrode 136 includes the overlapping portion 136B that overlaps the first connection electrode 126C. With such a configuration, an electric field that may be created between the first connection electrode 126C and the first pixel electrode 125α is blocked by the overlapping portion 136B. Accordingly, a potential of the first pixel electrode 125α is preferably maintained.

The openings 136A of the common electrode 136 include the first slits 136A1 and the second slits 136A2. The first slit 136A1 extends along the first direction toward the first connection electrode 126C. The second slit 136A2 extends along the first direction toward an opposite side from the first connection electrode 126C. The second slit 136A2 is longer than the first slit 136A1. The first slit 136A1, which extends along the first direction toward the first connection electrode 126C, has a length so as not to overlap the first connection electrode 126C. The second slit 136A2, which extends along the first direction toward an opposite side from the first connection electrode 126C, is longer than the first slit 136A1. Therefore, even with the length of the first slit 136A1 being limited to a certain length or shorter, a sufficient opening area of the opening 136A can be obtained.

### Third Embodiment

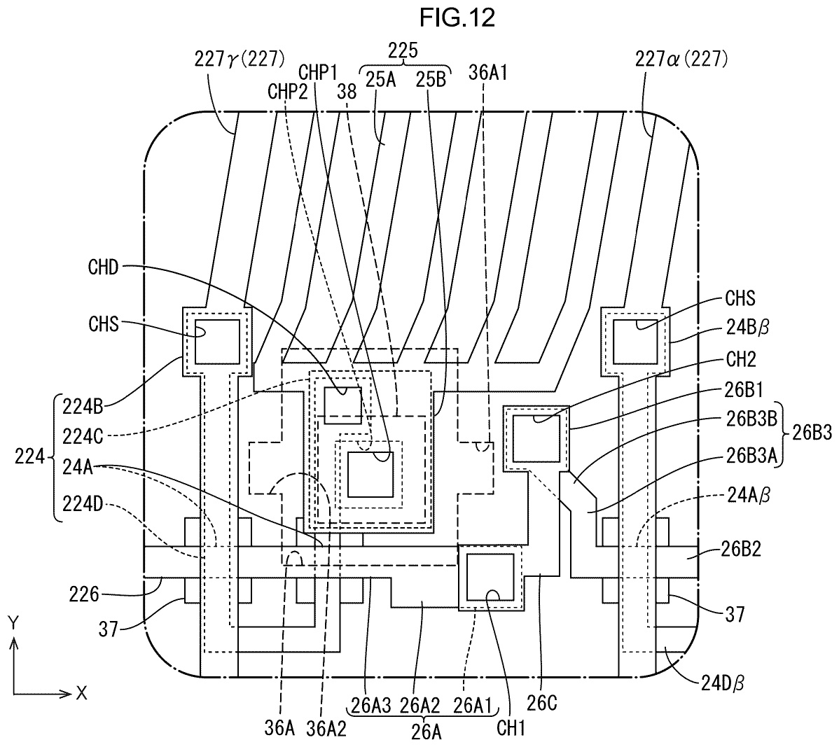

A third embodiment will be described with reference to FIG. 12. The third embodiment includes TFTs 224 having a configuration different from the configuration of the first embodiment. Configuration, operations, and effects similar to those of the first embodiment may not be described.

As illustrated in FIG. 12, the TFT 224 of this embodiment includes a semiconductor section 224D that extends with being bent twice from a source electrode 224B to a drain electrode 224C. More in detail, the semiconductor section 224D extends from a first end portion overlapping the source electrode 224B along the Y-axis direction to overlap the source line 227 with a predefined length. The semiconductor section 224D is bent after crossing a gate line 226 and extend along the X-axis direction toward the drain electrode 224C (rightward in FIG. 12). Then, the semiconductor section 224D is bent again and extends along the Y-axis direction toward the drain electrode 224C (upward in FIG. 12) to the drain electrode 224C. With such a configuration of the semiconductor section 224D, the drain electrode 224C is closer to the source electrode 224B of the TFT 224 in the X-axis direction compared to the configuration of the first embodiment. For instance, the first drain electrode 224C of a first TFT 224α is closer to a third source line 227γ than the first source line 227α in the X-axis direction. Thus, with the drain electrode 224C being disposed closer to the source electrode 224B in the X-axis direction, a space between two source lines 227 that are adjacent to each other in the X-axis direction and a short-side dimension of a pixel electrode 225 are reduced compared to the first embodiment (refer to FIG. 7). Accordingly, an interval between the pixels PX can be shorter and high resolution is preferably achieved.

### Fourth Embodiment

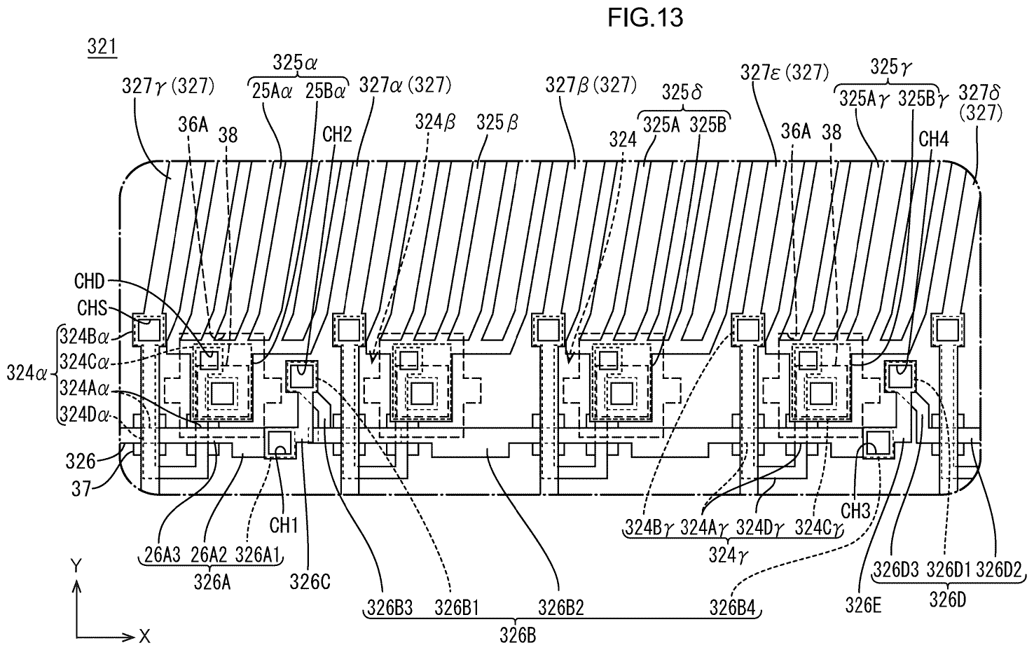

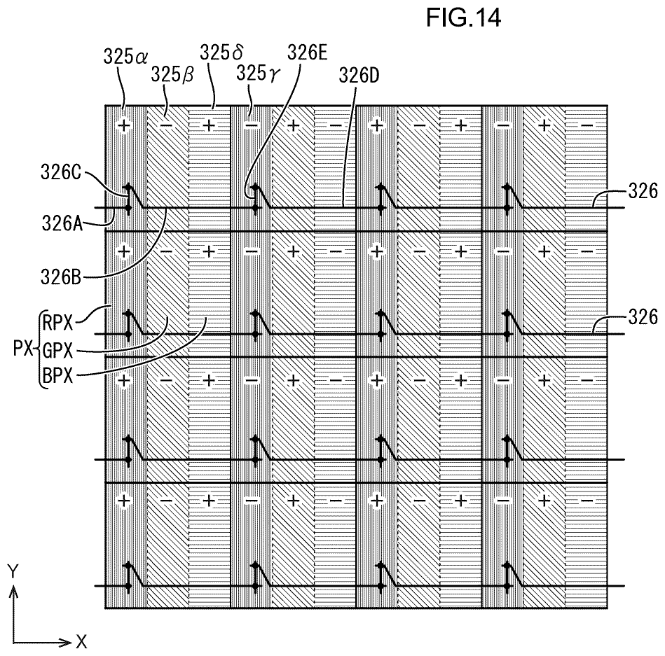

A fourth embodiment will be described with reference to FIGS. 13 and 14. The fourth embodiment includes a gate line 336 having a configuration different from the configuration of the third embodiment. Configuration, operations, and effects similar to those of the first and third embodiments may not be described.

As illustrated in FIG. 13, a gate line 326 at least includes a third line section 326D and a second connection electrode 326E in addition to a first line section 326A, a second line section 326B, and a first connection electrode 326C. The third line section 326D is a portion of the second metal film and extends along the X-axis direction similar to the first line section 326A and the second line section 326B. Similar to the first connection electrode 326C, the second connection electrode 326E is a portion of the third metal film and extends along the Y-axis direction and is connected to the second line section 326B and the third line section 326D.

As illustrated in FIG. 13, five source lines 327 that are arranged along the X-axis direction include a third source line 327γ that crosses the first line section 326A, a first source line 327α and a second source line 327β that cross the second line section 326B, a fourth source line 327δ (a fifth line), and a fifth source line 327ε (a sixth line). The fourth source line 327δ is disposed on an opposite side (a right side in FIG. 13) from the first source line 327α with respect to the second source line 327β in the X-axis direction and spaced from the second source line 327β in the X-axis direction. The fifth source line 327ε is disposed closer to the second source line 327β (on a left side in FIG. 13) than the fourth source line 327δ is in the X-axis direction and spaced from the fourth source line 327δ in the X-axis direction. Four pixel electrodes 325 arranged along the X-axis direction include a first pixel electrode 325α, a second pixel electrode 325β, a third pixel electrode 325γ, and a fourth pixel electrode 325δ. The third pixel electrode 325γ is disposed between the fourth source line 327δ and the fifth source line 327ε. The fourth pixel electrode 325δ is disposed between the second source line 327β and the fifth source line 327ε. A pixel electrode body 325A included in the third pixel electrode 325γ is defined as a third pixel electrode body 325Aγ. A connection portion 325B included in the third pixel electrode 325γ is defined as a third connection portion 325Bγ. Five TFTs 324 arranged along the X-axis direction include a first TFT 324α, a second TFT 324β, and a third TFT 324γ (a third switching component) that is connected to the third pixel electrode 325γ. A gate electrode 324A included in the third TFT 324γ is defined as a third gate electrode 324Aγ (a seventh electrode). A source electrode 324β included in the third first TFT 324γ is defined as a third source electrode 324Bγ (an eighth electrode). A drain electrode 324C included in the third TFT 324γ is defined as a third drain electrode 324Cγ (a fifth electrode). A semiconductor section 324D of the third TFT 324γ is defined as a third semiconductor section 324Dγ. The third drain electrode 324Cγ is disposed on the same side (an upper side in FIG. 13) as the first drain electrode 324Cα with respect to the gate line 326 in the Y-axis direction and spaced from the gate line 326. The third drain electrode 324Cγ is disposed between the fourth source line 327δ and the fifth source line 327ε.

As illustrated in FIG. 13, the third TFT 324γ is driven based on the signal supplied to the third gate electrode 324Aγ via the gate line 326 similarly to the first TFT 324α and the second TFT 324β. The image signal supplied from the driver 12 to the fifth source line 327γ is supplied to the third drain electrode 324Cγ via the third semiconductor section 324Dγ from the third source electrode 324Bγ, and the third pixel electrode 325γ is charged at a potential related to the supplied image signal.

As illustrated in FIG. 13, the third line section 326D is disposed adjacent to and on the right side of the second line section 326B in FIG. 13. A border between the second line section 326B and the third line section 326D is between the fourth source line 327δ and the fifth source line 327ε with respect to the X-axis direction and is between the third drain electrode 324Cγ and the fourth source line 327δ with respect to the X-axis direction. The second line section 326B has two end portions with respect to the X-axis direction. One of the two end portions on an opposite side from a second end portion 326B1 (on the third line section 326D side, on the right side in FIG. 13) is defined as a third end portion 326B4. The third end portion 326B4 is disposed between the third drain electrode 324Cγ and the fourth source line 3278. More in detail, the third end portion 326B4 is closer to the third drain electrode 324Cγ than the fourth source line 327δ with respect to the X-axis direction. The third line section 326D has two end portions with respect to the X-axis direction. One of the two end portions close to the second line section 326B (on the left side in FIG. 13) is defined as a fourth end portion 326D1. The fourth end portion 326D1 is disposed between the third drain electrode 324Cγ and the fourth source line 3278. More in detail, the fourth end portion 326D1 is closer to the fourth source line 327δ than the third drain electrode 324Cγ with respect to the X-axis direction. The fourth end portion 326D1 is disposed on the same side (on the upper side in FIG. 13) as the third drain electrode 324Cγ with respect to the third end portion 326B4 in the Y-axis direction. The fourth end portion 326D1 is spaced from the third end portion 326B4 with respect to the Y-axis direction. More in detail, the fourth end portion 326D1 is disposed between the third end portion 326B4 and the third pixel electrode body 325Aγ of the third pixel electrode 325γ in the Y-axis direction. The fourth end portion 326D1 is closer to the third pixel electrode body 325Aγ in the Y-axis direction than the third end portion 326B4 is.

As illustrated in FIG. 13, a first end portion of the second connection electrode 326E overlaps the third end portion 326B4 of the second line section 326B and a second end portion of the second connection electrode 326E overlaps the fourth end portion 326D1 of the third line section 326D. The second connection electrode 326E extends substantially along the Y-axis direction so as to extend from the third end portion 326B4 of the second line section 326B to the fourth end portion 326D1 of the third line section 326D. More in detail, the second connection electrode 326E extends from the third end portion 326B4 toward the fourth source line 327δ along the X-axis direction and is bent upwardly and extends to the fourth end portion 326D1 along the Y-axis direction. The first interlayer insulating film 33 includes a third contact hole CH3 in a portion overlapping the third end portion 326B4 of the second line section 326B and the first end portion of the second connection electrode 326E and a fourth contact hole CH4 in a portion overlapping the fourth end portion 326D1 of the third line section 326D and the second end portion of the second connection electrode 326E.

With the gate line 326 having such a configuration, operations and advantageous effects described below are obtained. In a process of producing an array substrate 321, with the second metal film being formed and patterned, the first line section 326A, the second line section 326B, and the third line section 326D of the gate line 326 are formed. At this time, the first line section 326A, the second line section 326B, and the third line section 326D are not connected to each other and therefore, electrostatic discharge is less likely to be caused in the first line section 326A, the second line section 326B, and the third line section 326D due to separation charge compared to a configuration in which the gate line is only a portion of the second metal film and the first line section and the second line section are connected. With the first interlayer insulating film 33 being formed and patterned after patterning the second metal film, in addition to the first contact hole CH1 and the second contact hole CH2, the third contact hole CH3 is formed in a portion of the first interlayer insulating film 33 overlapping the third end portion 326B4 of the second line section 326B and the fourth contact hole CH4 is formed in a portion of the first interlayer insulating film 33 overlapping the fourth end portion 326D1 of the third line section 326D. Then, with the third metal film being formed and patterned, the source lines 327α-327ε, the drain electrodes 324Cα-324Cγ, and the connection electrodes 326C and 326E are formed. The second connection electrode 326E is connected to the third end portion 326B4 of the second line section 326B via the third contact hole CH3 and is connected to the fourth end portion 326D1 of the third line section 326D via the fourth contact hole CH4. The first line section 326A, the second line section 326B, the third line section 326D, the first connection electrode 326C, and the second connection electrode 326E are connected to each other and configured as the gate line 326.

As illustrated in FIG. 13, the second connection electrode 326E extends from the third end portion 326B4 to the fourth end portion 326D1. The fourth end portion 326D1 is disposed on the same side as the third drain electrode 324Cγ with respect to the third end portion 326B4 in the Y-axis direction and the fourth end portion 326D1 is spaced from the third end portion 326B4 with respect to the Y-axis direction. Furthermore, the fourth end portion 326D1 is disposed between the fourth source line 327δ and the third drain electrode 324Cγ in the X-axis direction. With such a configuration, the space between the third drain electrode 324Cγ and the fourth source line 327δ in the X-axis direction can be reduced with keeping enough space between the second connection electrode 326E and the third drain electrode 324Cγ in the X-axis direction and enough space between the second connection electrode 326E and the fourth source line 327δ Accordingly, high resolution is preferably achieved. Similar to the second line section 326B, the third line section 326D includes a body section 326D2 that extends on the same straight line as the second line section 326B and a bent section 326D3 that is bent from the body section 326D2 and extends to the fourth end portion 326D1. Configurations of the body section 326D2 and the bent section 326D3 of the third line section 326D are similar to those of the body section 326B2 and the bent section 326B3 of the second line section 326B and will not be described in detail. Similar to the first connection electrode 326C, the second connection electrode 326E is disposed between the second line section 326B and the third pixel electrode body 325Aγ in the Y-axis direction. Similar to the first end portion 326A1 and the second end portion 326B1, the third end portion 326B4 and the fourth end portion 326D1 partially overlap with respect to the X-axis direction.

As illustrated in FIG. 13, the second line section 326B has a non-separated structure between the first source line 327α and the fifth source line 327δ in the X-axis direction. Namely, the second line section 326B crosses the first source line 327α, the second source line 327β, and the fifth source line 327ε. Therefore, the first connection electrode 326C and the second connection electrode 326E are not disposed corresponding to the pixel PX including the second pixel electrode 325β that is between the first source line 327α and the second source line 327β, which cross the second line section 426B. Similarly, the first connection electrode 326C and the second connection electrode 326E are not disposed corresponding to the pixel PX including the fourth pixel electrode 325δ that is between the second source line 327β and the fifth source line 327ε, which cross the second line section 326B. The first connection electrode 326C is disposed corresponding to the pixel PX including the first pixel electrode 325α that is between the third source line 327γ crossing the first line section 326A and the second source line 327β crossing the second line section 326B. Similarly, the second connection electrode 326E is disposed corresponding to the pixel PX including the third pixel electrode 325γ that is between the fifth source line 327E crossing the second line section 326B and the fourth source line 327δ crossing the third line section 326D. Namely, with the pixel PX corresponding to the first connection electrode 26C being the nth (n: integer of 1 or greater) one from the left end in FIG. 13 in the display area AA, the pixel PX corresponding to the second connection electrode 326E is the (n+2)th one from the left end in FIG. 13 in the display area AA. Therefore, the color filter 28 opposed to the first pixel electrode 325α and the color filter 28 opposed to the third pixel electrode 325γ exhibit a same color. For instance, with the first pixel electrode 325α being opposed to the color filter 28 exhibiting red, the first pixel electrode 325α and the opposed red color filter 28 are configured as a red pixel RPX. In such a configuration, the third pixel electrode 325γ is opposed to the color filter 28 exhibiting red and the third pixel electrode 325γ and the opposed red color filter 28 are configured as another red pixel RPX. With each of the first pixel electrode 325α and the third pixel electrode 325γ being configured as a part of the red pixel RPX, the second pixel electrode 325β is configured as a part of a green pixel GPX and the fourth pixel electrode 325δ is configured as a part of a blue pixel BPX.

The polarity of each pixel electrode 325 will be described with reference to FIG. 14. In FIG. 14, the pixel electrodes 325 and the gate lines 326 are schematically illustrated and the positive polarity and the negative polarity of the pixel electrodes 325 are illustrated with the symbols “+” and “−”, respectively. The source lines 327 are not illustrated in FIG. 14; however, the source line 327 is disposed between every two pixel electrodes 325 that are adjacent to each other in the X-axis direction. In FIG. 14, the pixel electrodes 325 of the red pixels RPX, the pixel electrodes 325 of the green pixels GPX, and the pixel electrodes 325 of the blue pixels BPX are illustrated with different kinds of shadings. As illustrated in FIG. 14, the pixel electrode 325 is charged at a potential based on the image signal supplied to the corresponding source line 327 from the driver 12 (refer to FIG. 1). The driver 12 supplies the image signals to the source lines 327 such that every two source lines 327 that are adjacent to each other in the X-axis direction receive the image signals of opposite polarities. Specifically, with the odd numbered source line 327 from one end of the display area AA in the X-axis direction receiving an image signal of the positive polarity (+), the even numbered source line 327 from the one end of the display area in the X-axis direction receives an image signal of the negative polarity (−). On the other hand, with the odd numbered source line 327 from the one end of the display area AA in the X-axis direction receiving an image signal of the negative polarity (−), the even numbered source line 327 from the one end of the display area in the X-axis direction receives an image signal of the positive polarity (+). Thus, the driver 12 performs polarity inversion driving (line inversion driving) with which the polarities of the image signals supplied to the odd numbered source lines 327 and the even numbered source lines 327 are periodically inverted.

As illustrated in FIG. 14, the first pixel electrode 325α and the third pixel electrode 325γ are configured as parts of the red pixels RPX, respectively, the second pixel electrode 325β is configured as a part of a green pixel GPX, and the fourth pixel electrode 325δ is configured as a part of a blue pixel BPX. The first pixel electrode 325α configured as a part of the red pixel RPX that corresponds to the first connection electrode 326C is charged at a potential of the polarity based on the image signal supplied to the third source line 327γ. The third pixel electrode 325γ configured as a part of the red pixel RPX that corresponds to the second connection electrode 326E is charged at a potential of the polarity based on the image signal supplied to the fifth source line 327ε. With the third source line 327γ being an odd numbered one from the one end of the display area AA in the X-axis direction, the fifth source line 327ε is an even numbered one from the one end of the display area AA in the X-axis direction. Therefore, the image signals supplied from the driver 12 to the third source line 327γ and the fifth source line 327¿ have opposite polarities and the first pixel electrode 325α and the third pixel electrode 325γ also have opposite polarities.

Potential change is caused in the gate lines 326 by inputting of the signals for driving the TFTs 324. The potential change in the gate lines 326 may affect the potential of the pixel electrodes 325 due to parasitic capacitances caused between the gate lines 326 and the pixel electrodes 325. Specifically, if the potential of the gate line 326 falls from a high potential to a low potential, the potential (Vd) of the pixel electrode 325 is shifted to a minus side due to the parasitic capacitance created between the gate line 326 and the pixel electrode 325. Such level shift is defined as level shift voltage (ΔVd). At this time, with respect to the pixel electrode 325 having a potential related to the image signal of the positive polarity (a positive potential), a potential difference between the potential of the pixel electrode 325 and the high potential is small. Therefore, the TFT 324 becomes off shortly after the level shift occurs. On the other hand, with respect to the pixel electrode 325 having a potential related to the image signal of the negative polarity (a negative potential), a potential difference between the potential of the pixel electrode 325 and the high potential is large. Therefore, it takes a certain time until the TFT 324 becomes off shortly after the level shift occurs. Therefore, before the TFT 324 becomes off, the pixel electrode 325 is charged again and the potential of the pixel electrode is shifted to a plus side and this reduces the level shift voltage. Thus, the level shift voltage differs between the pixel electrode 325 having a positive potential and the pixel electrode 325 having a negative potential. Furthermore, the first pixel electrode 325α and the third pixel electrode 325γ are disposed closer to the first connection electrode 326C and the second connection electrode 326E, respectively, than the second pixel electrode 325β and the fourth pixel electrode 325δ. In the first pixel electrode 325α and the third pixel electrode 325γ, the potential level shift caused due to the parasitic capacitance created between the gate line 326 and the pixel electrode 325 becomes larger. Therefore, if the potentials of the first pixel electrode 325α and the third pixel electrode 325γ have a same polarity, display unevenness of a stripe shape may be likely to be recognized. In this respect, since the image signals supplied from the driver 12 to the third source line 327γ and the fifth source line 327δ have opposite polarities, the first pixel electrode 325α and the third pixel electrode 325γ also have opposite polarities when being charged. Therefore, even with the potential level shift caused due to the parasitic capacitance created between the gate line 326 and the pixel electrode 325 being larger in the first pixel electrode 325α and the third pixel electrode 325γ than the second pixel electrode 325β and the fourth pixel electrode 325δ, display unevenness of a stripe shape is less likely to be recognized.

As illustrated in FIG. 14, the gate line 326 of this embodiment is configured such that the line sections 326A, 326B, 326D cross three source lines 327. Therefore, each of the number of the first line sections 326A, the number of the second line sections 326B, the number of the third line sections 326D is about one third of the number of the pixels PX arranged along the X-axis direction and each of the number of the first connection electrodes 326C and the number of the second connection electrodes 326E is also about one third of the number of the pixels PX arranged along the X-axis direction.

As previously described, the present embodiment includes the third source line 327γ (a fourth line), the fourth source line 327δ (a fifth line), the fifth source line 327ε (a sixth line), the third drain electrode 324Cγ (a fifth electrode), the third TFT 324γ (a third switching component), the third pixel electrode 325γ, and the driver 12 (a signal supply section). The third source line 327γ extends along the second direction and is disposed such that the first pixel electrode 325α is between the third source line 327γ and the first source line 327α with respect to the first direction. The fourth source line 327δ extends along the second direction and is disposed on an opposite side from the first source line 327α with respect to the second source line 327β in the first direction and spaced from the second source line 327β. The fifth source line 327ε extends along the second direction and is disposed on the second source line 327β side with respect to the fourth source line 327δ with respect to the first direction and spaced from the fourth source line 327δ. The third drain electrode 324Cγ is disposed on the same side as the first drain electrode 324Cα with respect to the gate line 326 in the second direction and spaced from the gate line 326. The third drain electrode 324Cγ is between the fourth source line 327δ and the fifth source line 327ε in the first direction. The third TFT 324γ includes the third drain electrode 324Cγ. The third pixel electrode 325γ is disposed between the fourth source line 327δ and the fifth source line 327ε in the first direction and connected to the third drain electrode 324Cγ. The driver 12 supplies image signals to each of the first source line 327α, the second source line 327β, the third source line 327γ, the fourth source line 327δ, and the fifth source line 327ε. The gate line 326 includes the third line section 326D and the second connection electrode 326E. The third line section 326D is a portion of the second metal film that is different from the portions of the second metal configured as the first line section 326A and the second line section 326B. The second connection electrode 326E is a portion of the third metal film that is different from the portions of the third metal film configured as the first connection electrode 326C, the first source line 327α, the first drain electrode 324Cα, and the second source line 327β. The third source line 327γ is a portion of the third metal film that is different from the portions of the third metal film configured as the first connection electrode 326C, the first source line 327α, the first drain electrode 324Cα, the second source line 327β, and the second connection electrode 326E. The fourth source line 327δ is a portion of the third metal film that is different from the portions of the third metal film configured as the first connection electrode 326C, the first source line 327α, the first drain electrode 324Cα, the second source line 327β, the second connection electrode 326E, and the third source line 327γ. The fifth source line 327δ is a portion of the third metal film that is different from the portions of the third metal film configured as the first connection electrode 326C, the first source line 327α, the first drain electrode 324Cα, the second source line 327β, the second connection electrode 326E, the third source line 327γ, and the fourth source line 327δ. The third drain electrode 324Cγ is a portion of the third metal film that is different from the portions of the third metal film configured as the first connection electrode 326C, the first source line 327α, the first drain electrode 324Cα, the second source line 327β, the second connection electrode 326E, the third source line 327γ, the fourth source line 327δ, and the fifth source line 327ε. The second line section 326B includes the third end portion 326B4 that is on an opposite side from the second end portion 326B1. The third line section 326D includes the fourth end portion 326D1 that is disposed on the same side as the third drain electrode 324Cγ with respect to the third end portion 326B4 in the second direction. The fourth end portion 326D1 is disposed between the third drain electrode 324Cγ and the fourth source line 327δ with respect to the first direction. The second connection electrode 326E extends from the third end portion 326B4 to the fourth end portion 326D1. The first interlayer insulating film 33 includes the third contact hole CH3 in a portion overlapping the third end portion 326B4 and the second connection electrode 326E and the fourth contact hole CH4 in a portion overlapping the fourth end portion 326D1 and the second connection electrode 326E. The first TFT 324α includes the first source electrode 324Bα (the sixth electrode) that is a portion of the third source line 327γ and the first semiconductor section 324Dα that is made of semiconductor material and connected to the first drain electrode 324Cα and the first source electrode 324Bα. The third TFT 324γ includes the third gate electrode 324Aγ (the seventh electrode) that is a portion of the second line section 326B, the third source electrode 324Bγ (the eighth electrode) that is a portion of the fifth source line 327ε, and the third semiconductor section 324Dγ that is made of semiconductor material and connected to the third drain electrode 324Cγ and the third source electrode 324Bγ. At least the image signals supplied from the driver 12 to the third source line 327γ and the fifth source line 327ε have opposite polarities.

The second connection electrode 326E is connected to the third end portion 326B4 of the second line section 326B via the third contact hole CH3 and is connected to the fourth end portion 326D1 of the third line section 326D via the fourth contact hole CH4. The second connection electrode 326E extends from the third end portion 326B4 to the fourth end portion 326D1. The fourth end portion 326D1 is disposed on the same side as the third drain electrode 324Cγ with respect to the third end portion 326B4 in the second direction and the fourth end portion 326D1 is spaced from the third end portion 326B4 with respect to the second direction. The fourth end portion 326D1 is disposed between the fourth source line 327δ and the third drain electrode 324Cγ in the first direction. With such a configuration, the space between the third drain electrode 324Cγ and the fourth source line 327δ can be reduced with keeping enough space between the second connection electrode 326E and the third drain electrode 324Cγ and enough space between the second connection electrode 326E and the fourth source line 327δ. Accordingly, high resolution is preferably achieved.

With the first TFT 324α being driven based on the signal supplied to the first gate electrode 324Aα via the gate line 326, the image signal supplied to the first source electrode 324Bα via the third source line 327γ is supplied to the first drain electrode 324Cα via the first semiconductor section 324Dα. The first pixel electrode 325α that is connected to the first drain electrode 324Cα is charged at a potential of a polarity related to the supplied image signal. With the third TFT 324γ being driven based on the signal supplied to the third gate electrode 324Aγ via the gate line 326, the image signal supplied to the third source electrode 324Bγ via the fifth source line 327ε is supplied to the third drain electrode 324Cγ via the third semiconductor section 324Dγ. The third pixel electrode 325γ that is connected to the third drain electrode 324Cγ is charged at a potential of a polarity related to the supplied image signal.

Potential change is caused in the gate lines 326 by inputting of the signals for driving the TFTs 324. The potential change in the gate lines 326 may affect the potential of the pixel electrodes 325 due to parasitic capacitances caused between the gate lines 326 and the pixel electrodes 325 and causes level shift voltage. In the pixel electrode 325 having a potential of the negative polarity, the level shift voltage tends to reduce compared to the pixel electrode 325 having a potential of the positive polarity. Particularly, the first pixel electrode 325α and the third pixel electrode 325γ are disposed closer to the first connection electrode 326C and the second connection electrode 326E, respectively, compared to the second pixel electrode 325β. Therefore, in the first pixel electrode 325α and the third pixel electrode 325γ, the potential level shift caused due to the parasitic capacitance created between the gate line 326 and the pixel electrode 325 becomes larger. Therefore, if the potentials of the first pixel electrode 325α and the third pixel electrode 325γ have a same polarity, display unevenness of a stripe shape may be likely to be recognized. In this respect, since the image signals supplied from the driver 12 to the third source line 327γ and to the fifth source line 327δ have opposite polarities, the first pixel electrode 325α and the third pixel electrode 325γ also have opposite polarities when being charged. Therefore, even with the potential level shift caused due to the parasitic capacitance created between the gate line 326 and the pixel electrode 325 being larger in the first pixel electrode 325α and the third pixel electrode 325γ than the second pixel electrode 325β and the fourth pixel electrode 325δ, display unevenness of a stripe shape is less likely to be recognized.

### Fifth Embodiment

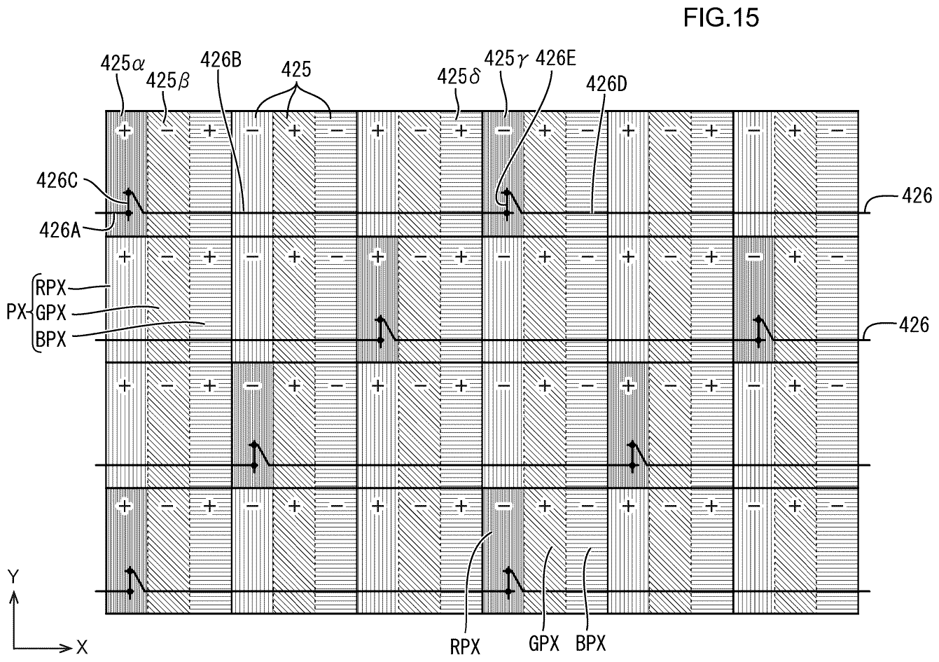

A fifth embodiment will be described with reference to FIG. 15. In the fifth embodiment, arrangement of third pixel electrodes 425γ and a configuration of gate lines 426 are altered from those of the fourth embodiment. Configuration, operations, and effects similar to those of the fourth embodiment may not be described.

In FIG. 15, similar to FIG. 14, pixel electrodes 425 and the gate lines 426 are schematically illustrated and the polarities of the pixel electrodes 425 are illustrated with the symbols of “+” and “−”. In FIG. 15, similar to FIG. 14, the source lines 27 are not illustrated; however, the source lines 27 are disposed between every two pixel electrodes 425 that are adjacent to each other in the X-axis direction. In FIG. 15, the pixel electrodes 425 of the red pixels RPX, the pixel electrodes 425 of the green pixels GPX, and the pixel electrodes 425 of the blue pixels BPX are illustrated with different kinds of shadings. In FIG. 15, each of a first pixel electrode 425α and a third pixel electrode 425γ is configured as a part of the red pixel RPX, a second pixel electrode 425β is configured as a part of the green pixel GPX, and a fourth pixel electrode 425δ is configured as a part of the blue pixel BPX.

As illustrated in FIG. 15, the third pixel electrode 425γ is disposed such that eight pixel electrodes 425 (including the second pixel electrode 425β and the fourth pixel electrode 425δ) are disposed between the third pixel electrode 425γ and the first pixel electrode 425α with respect to the X-axis direction. A second line section 426B is configured to cross nine source lines 27 (the first source line 27α, the second source line 27β, the third source line 27γ, and the fourth source line 27δ (refer to FIG. 13)). The number of the source lines 27 that cross the second line section 426B is defined by 3m (m: odd number) and m is three in this embodiment. The number of the source lines 27 that cross the second line section 326B in the fourth embodiment is three and m is one in 3m. Therefore, in this embodiment, the third source line 27γ via which the image signals are supplied to the first pixel electrode 425α corresponds to the odd numbered one from the one end of the display area AA in the X-axis direction and the fifth source line 27ε via which the image signals are supplied to the third pixel electrode 425γ corresponds to the even numbered one from the one end of the display area AA in the X-axis direction.

The driver 12 performs the line inversion driving similar to the fourth embodiment. The image signals supplied from the driver 12 to the third source line 27γ and the fifth source line 27ε have opposite polarities and the first pixel electrode 425α and the third pixel electrode 425γ also have opposite polarities. In this embodiment, display unevenness that is caused by the potential change in the gate lines 426 is less likely to be recognized similar to the fourth embodiment.

As illustrated in FIG. 15, the gate line 426 of this embodiment is configured such that the line sections 426A, 426B, 426D cross the nine source lines 27. Therefore, each of the number of the first line sections 426A, the number of the second line sections 426B, the number of the third line sections 426D is about one ninth of the number of the pixels PX arranged along the X-axis direction and each of the number of the first connection electrodes 426C and the number of the second connection electrodes 426E is also about one nineth of the number of the pixels PX arranged along the X-axis direction. Thus, with the number of the connection electrodes 426C, 426E being reduced compared to that in the fourth embodiment, the number of connection portions of the line sections 426A, 426B, 426D and the connection electrodes 426C, 426E is also reduced. Accordingly, production yield is less likely to drop due to connection errors at the connection portions. The first pixel electrodes 425α and the third pixel electrodes 425γ are disposed such that the first pixel electrode 425α and the third pixel electrode 425γ in a first pixel row and the first pixel electrode 425α and the third pixel electrode 425γ in a second pixel row next to the first pixel row do not overlap with respect to the Y-axis direction.

### Sixth Embodiment

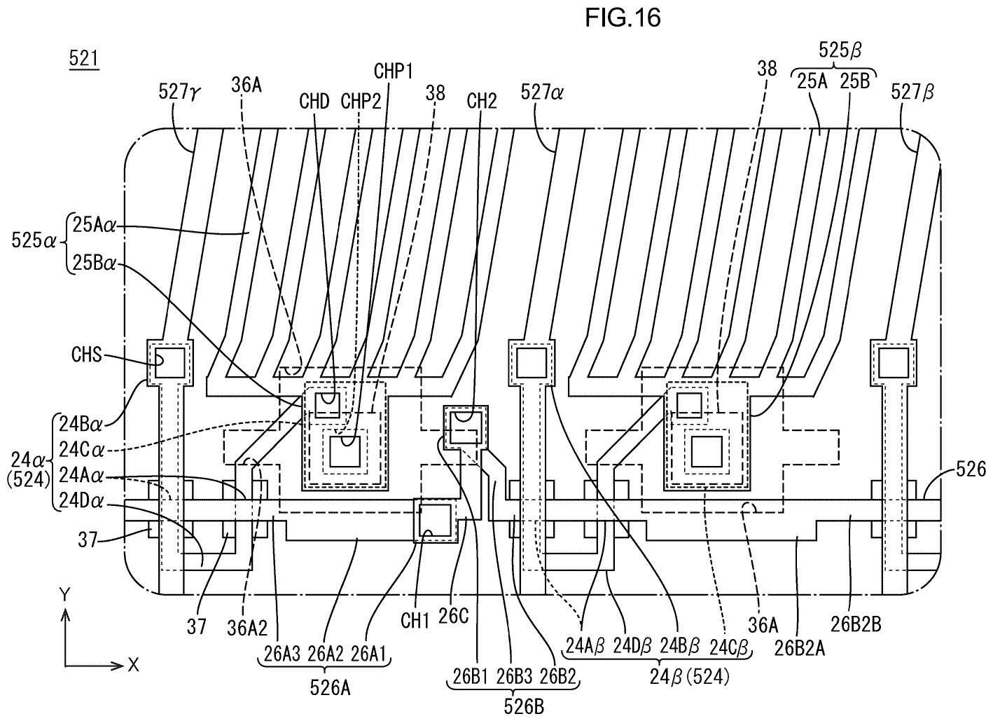

A sixth embodiment will be described with reference to FIGS. 16 to 18. In the sixth embodiment, pixel arrangement is altered from that of the fifth embodiment. Configuration, operations, and effects similar to those of the fifth embodiment may not be described.

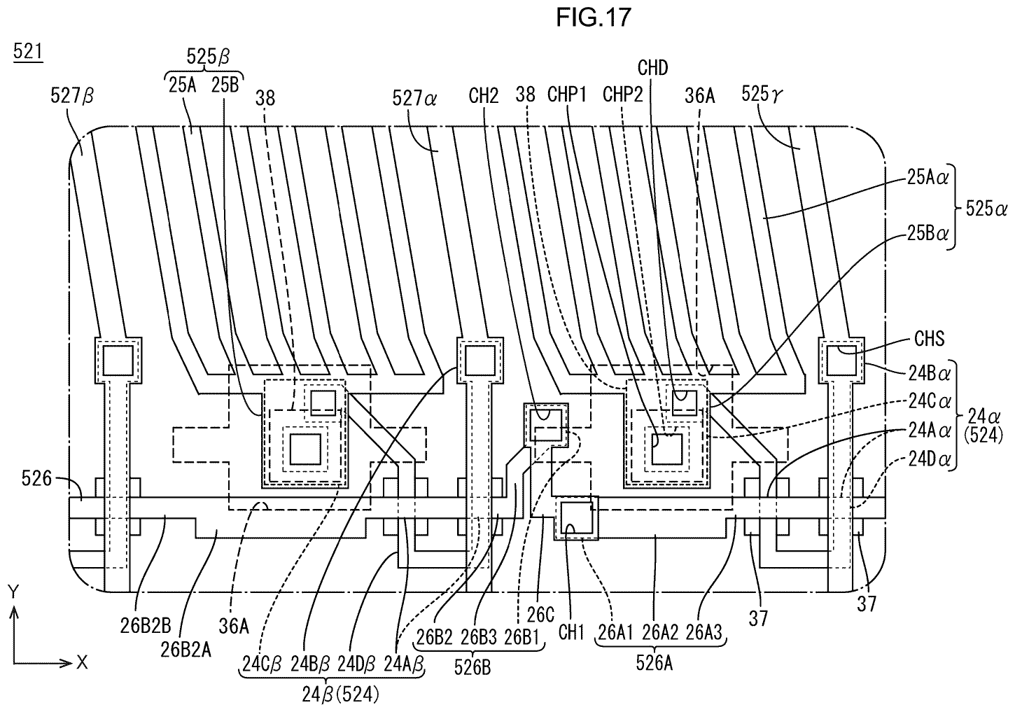

As illustrated in FIGS. 16 and 17, in an array substrate 521 according to this embodiment, every two adjacent pixel rows have an inverted pixel arrangement with respect to the right-left direction. The pixel arrangement illustrated in FIG. 16 is same as the pixel arrangement illustrated in FIG. 4. FIG. 16 illustrates the pixel arrangement of the even (odd) numbered pixel row from one end of the display area AA with respect to the Y-axis direction. In FIG. 16, a TFT 524 is configured such that an image signal is supplied to the pixel electrode 525 that is on the right side of the source line 527. FIG. 17 illustrates the pixel arrangement of the odd (even) numbered pixel row from the one end of the display area AA with respect to the Y-axis direction. In FIG. 17, the TFT 524 is configured such that an image signal is supplied to the pixel electrode 525 that is on the left side of the source line 527. Therefore, the image signals supplied to the source line 527 are supplied to the pixel electrodes 525 of the adjacent pixel rows that are adjacent to each other in the Y-axis direction and have different pixel arrangements on the right and left sides of the source line 527. In this embodiment, the source lines 527 are bent in a zig zag shape. In FIG. 17, a second line section 526B is on the left side of the first line section 526A.

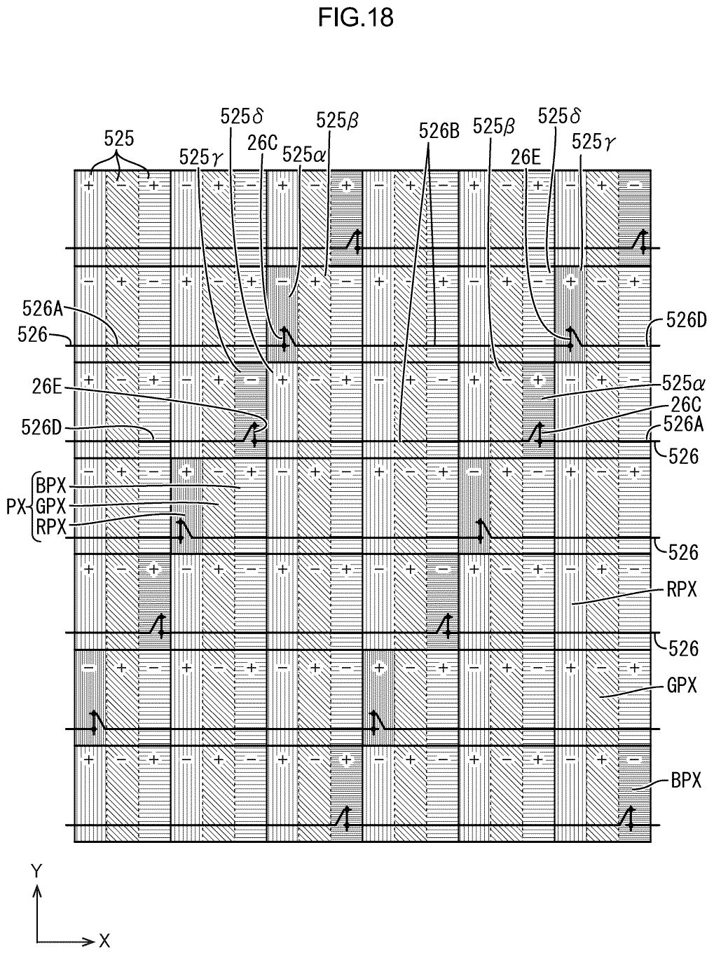

In FIG. 18, similar to FIG. 14, the pixel electrodes 525 and gate lines 526 are schematically illustrated and the polarities of the pixel electrodes 525 are illustrated with the symbols of “+” and “−”. In FIG. 18, similar to FIG. 14, the source lines 527 are not illustrated; however, the source lines 527 are disposed between every two pixel electrodes 525 that are adjacent to each other in the X-axis direction. In FIG. 18, the pixel electrodes 525 of the red pixels RPX, the pixel electrodes 525 of the green pixels GPX, and the pixel electrodes 525 of the blue pixels BPX are illustrated with different kinds of shadings.

As illustrated in FIG. 18, the third pixel electrode 525γ is disposed such that eight pixel electrodes 525 (including a second pixel electrode 525β and a fourth pixel electrode 525δ) are disposed between the third pixel electrode 525γ and the first pixel electrode 525α with respect to the X-axis direction. The second line section 526B is configured to cross nine source lines 527 (a first source line 527α, a second source line 527β, a third source line 527γ, and a fourth source line 527δ (refer to FIG. 13)).

Similar to the fourth and fifth embodiments, among the source lines 527 arranged along the X-axis direction, the polarities of the image signals supplied from the driver 12 to the odd numbered source lines 527 and the even numbered source lines 527 are periodically inverted. Therefore, the pixel electrodes 525 that are adjacent to each other in the X-axis direction have opposite polarities and the pixel electrodes 525 that are adjacent to each other in the Y-axis direction have opposite polarities. Namely, in this embodiment, the driver 12 performs Z-inversion driving. In this embodiment, similar to the fourth and fifth embodiments, the image signals supplied from the driver 12 to the third source line 527γ and the fifth source line 27ε from the driver 12 have opposite polarities and the first pixel electrode 325α and the third pixel electrode 325γ also have opposite polarities. Therefore, in this embodiment, display unevenness that is caused by the potential change in the gate lines 526 is less likely to be recognized similar to the fourth and fifth embodiments.

In this embodiment, the first pixel electrode 525α and the third pixel electrode 525γ in different pixel rows are configured as parts of pixels RPX of different colors. In FIG. 18, in the odd (even) numbered pixel rows from the one end of the display area AA in the Y-axis direction, the first pixel electrode 525α and the third pixel electrode 525γ are configured as parts of blue pixels BPX. In the even (odd) numbered pixel rows from the one end of the display area AA in the Y-axis direction, the first pixel electrode 525α and the third pixel electrode 525γ are configured as parts of red pixels RPX.

As illustrated in FIG. 18, the gate line 526 of this embodiment is configured such that the line sections 526A, 526B, 526D cross the nine source lines 527. Therefore, each of the number of the first line sections 526A, the number of the second line sections 526B, the number of the third line sections 526D is about one ninth of the number of the pixels PX arranged along the X-axis direction and each of the number of the first connection electrodes 526C and the number of the second connection electrodes 526E is also about one nineth of the number of the pixels PX arranged along the X-axis direction. The first pixel electrodes 525α and the third pixel electrodes 525γ are disposed such that the first pixel electrode 525α and the third pixel electrode 525γ in a first pixel row and the first pixel electrode 525α and the third pixel electrode 525γ in a second pixel row next to the first pixel row do not overlap with respect to the Y-axis direction.

### Seventh Embodiment

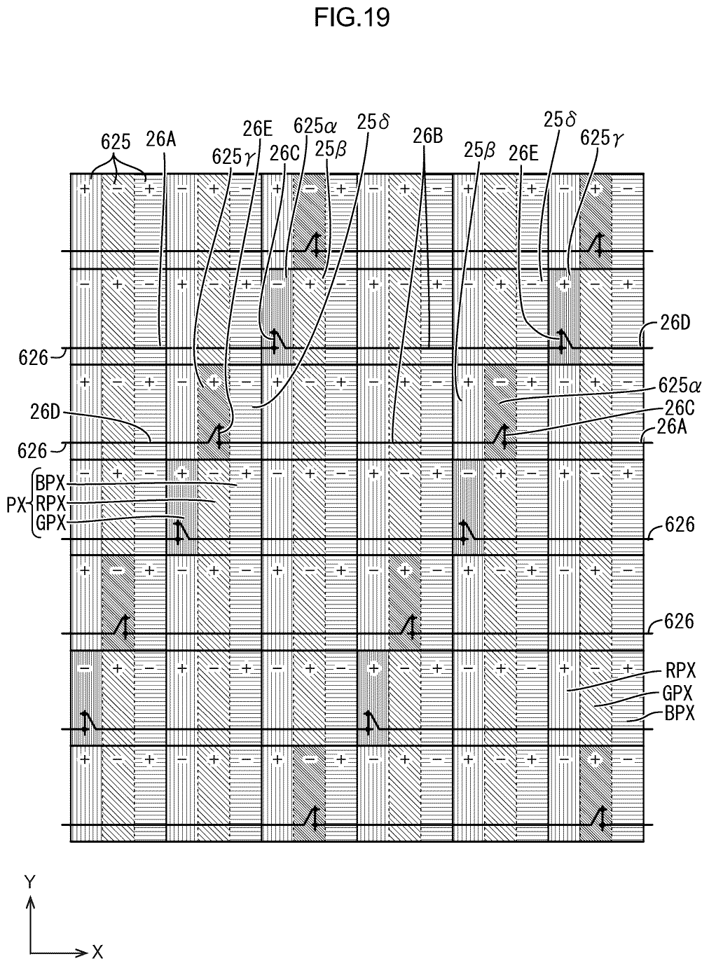

A seventh embodiment will be described with reference to FIG. 19. In the seventh embodiment, a color of pixels PX including first pixel electrodes 625α and a color of pixels PX including third pixel electrodes 625γ are altered from the sixth embodiment. Configuration, operations, and effects similar to those of the sixth embodiment may not be described.

In FIG. 19, similar to FIG. 14, pixel electrodes 625 and gate lines 626 are schematically illustrated and the polarities of the pixel electrodes 625 are illustrated with the symbols of “+” and “−”. In FIG. 19, similar to FIG. 14, the source lines 27 are not illustrated; however, the source lines 27 are disposed between every two pixel electrodes 625 that are adjacent to each other in the X-axis direction. In FIG. 19, the pixel electrodes 625 of the red pixels RPX, the pixel electrodes 625 of the green pixels GPX, and the pixel electrodes 625 of the blue pixels BPX are illustrated with different kinds of shadings.

As illustrated in FIG. 19, in the odd (even) numbered pixel rows from one end of the display area AA in the Y-axis direction, the first pixel electrode 625α and the third pixel electrode 625γ are configured as parts of green pixels GPX. In the even (odd) numbered pixel rows from the one end of the display area AA in the Y-axis direction, the first pixel electrode 625α and the third pixel electrode 625γ are configured as parts of red pixels RPX. In this embodiment, display unevenness that is caused by the potential change in the gate lines 626 is less likely to be recognized similar to the fourth to sixth embodiments.

### Other Embodiments

The technology described herein is not limited to the embodiments described above and illustrated by the drawings. For example, the following embodiments will be included in the technical scope of the present technology.

(1) The first line section 26A, 126A, 326A, 426A, 526A may include a body section and a bent section similar to the second line section 26B, 326B, 426B, 526B. Namely, the first line section 26A, 126A, 326A, 426A, 526A may be configured such that the bent section bent from the body section is continuous to the first end portion 26A1, 326A1.

(2) The second line section 26B, 326B, 426B, 526B may not include the bent section 26B3, 436B3. In such a configuration, the first line section 26A, 126A, 326A, 426A, 526A and the second line section 26B, 326B, 426B, 526B may be disposed not to overlap with respect to the X-axis direction and the first connection electrode 26C, 126C, 326C, 426C may be disposed to extend from the first end portion 26A1, 326A1 to the second end portion 26B1, 126B1, 326B1 that are spaced from each other in the Y-axis direction. In such a configuration, the TFTs and the pixel electrodes that are adjacent to the first line section 26A, 126A, 326A, 426A, 526A in the Y-axis direction and the TFT 24, 224, 324, 524 and the pixel electrode 25, 225, 325, 425, 525, 625 that are adjacent to the second line section 26B, 326B, 426B, 526B in the Y-axis direction do not overlap with respect to the X-axis direction.

(3) Other than (1) and (2), the specific planar shape and the specific arrangement of the line section 26A, 126A, 326A, 426A, 526A, 26B, 326B, 426B, 526B, 326D, 426D, 526D of the gate line 26, 126, 226, 326, 426, 526, 626 and the connection electrode 26C, 126C, 326C, 426C, 326E, 426E may be altered from those illustrated in the drawings as appropriate.

(4) Other than the configurations of the fourth to seventh embodiments, the number of the source lines 327, 527 crossing the second line section 327B, 426B, 526B may be altered as appropriate. The number of the source lines 327, 527 crossing the second line section 327B, 426B, 526B may be defined by 3m (m: an odd number of 5 or greater).

(5) In the configurations of the sixth and seventh embodiments, in the odd (even) numbered pixel rows from the one end of the display area AA in the Y-axis direction, the first pixel electrode 525α, 625α and the third pixel electrode 525γ, 625γ may be configured as parts of blue pixels BPX. In the even (odd) numbered pixel rows from the one end of the display area AA in the Y-axis direction, the first pixel electrode 525α, 625α and the third pixel electrode 525γ, 625γ may be configured as parts of green pixels GPX.

(6) In the configurations of the sixth and seventh embodiments, all the first pixel electrode 525α, 625α and the third pixel electrode 525γ, 625γ may be configured as parts of pixels PX exhibiting a single color (red, green, or blue).

(7) The intermediate electrodes 38 may not be included. In such a configuration, the connection portion 25B, 325B of the pixel electrode 25, 225, 325, 425, 525, 625 may be directly connected to the drain electrode 24C, 124C, 224C, 324C. The opening 36A, 136A of the common electrode 36, 136 may partially overlap the drain electrode 24C, 124C, 224C, 324C.

(8) The specific planar shape and arrangement of the openings 36A, 136A of the common electrode 36, 136 may be altered from those illustrated in the drawings as appropriate.

(9) The configuration of the fourth to seventh embodiments may be combined with the configuration of the first embodiment.

(10) The configuration of the fourth to seventh embodiments may be combined with the configuration of the second embodiment.

(11) In the configuration of the second embodiment, the touch panel pattern may use a mutual-capacitance method other than the self-capacitance method.

(12) The driver 12, 112 may be mounted on the flexible substrate 13 through the chip-on-film (COF) technology.

(13) Material of the semiconductor film included in the semiconductor section 24D, 224D, 324D may be amorphous silicon material or oxide semiconductor material.

(14) The TFT 24, 224, 324, 524 may be a bottom gate TFT or a double gate TFT other than the top gate TFT illustrated in the drawings.

(15) The pixel electrodes 25, 225, 325, 425, 525, 625 may be portions of the first transparent electrode film and the common electrode 36, 136 may be a portion of the second transparent electrode film. In such a configuration, the common electrode 36, 136 may preferably include slits for controlling alignment.

(16) The planar shape of the liquid crystal panel 11, 111 may be vertically elongated rectangle, a square, a circle, a semicircle, a vertically elongated oval, an oval, or a trapezoid.

(17) The display mode of the liquid crystal panel 11, 111 may be the VA mode or the IPS mode other than the FFS mode.

(18) The liquid crystal panel 11, 111 may be a reflective liquid crystal panel or a semitransmissive liquid crystal panel other than the transmissive liquid crystal panel. With the liquid crystal panel 11, 111 being a reflective liquid crystal panel, the backlight unit is not necessary.

(19) Display panels other than the liquid crystal panel 11, 111 (such as organic EL display panels) may be used.

1. An array substrate comprising:
a first line extending along a first direction;
a second line extending along a second direction that crosses the first direction:
a first electrode that is spaced from the first line in the second direction and is spaced from the second line in the first direction; and
a first insulating film, wherein
the first line includes a first line section, a second line section, and a first connection electrode,
the first line section is a portion of a first conductive film that is disposed in a layer lower than the first insulating film, the second line section is a portion of the first conductive film that is different from the portion of the first conductive film configured as the first line section, and the first connection electrode is a portion of a second conductive film that is disposed in a layer upper than the first insulating film,
the second line is a portion of the second conductive film that is different from the portion of the second conductive film configured as the first connection electrode,
the first electrode is a portion of the second conductive film that is different from the portions of the second conductive film configured as the first connection electrode and the second line,
the first line section includes a first end portion,
the second line section includes a second end portion that is away from the first end portion in the second direction and on a same side as the first electrode with respect to the second direction, the second end portion is between the second line and the first electrode in the first direction,
the first connection electrode extends from the first end portion to the second end portion, and
the first insulating film includes a first contact hole in a portion overlapping the first end portion and the first connection electrode and a second contact hole in a portion overlapping the second end portion and the first connection electrode.

2. The array substrate according to claim 1, wherein
the first line section extends along the first direction,
the second line section includes a body section and a bent section,
the body section extends along the first direction and extends on a same straight line as the first line section extends, and
the bent section extends from the body section with being bent to the second end portion.

3. The array substrate according to claim 2, wherein the bent section is between the first connection electrode and the second line in the first direction.

4. The array substrate according to claim 1, wherein the first end portion and the second end portion are disposed to overlap with respect to the second direction.

5. The array substrate according to claim 1, further comprising:
a first switching component including the first electrode; and
a first pixel electrode that is connected to the first electrode, wherein
the first switching component includes a second electrode that is a portion of the first line section,
the first pixel electrode includes a first connection portion that is connected to the first electrode and a first pixel electrode body that is disposed on an opposite side from the first line with respect to the first connection portion in the second direction, and
the first connection electrode is disposed between the first line section and the first pixel electrode body with respect to the second direction.

6. The array substrate according to claim 1, further comprising:
a first switching component including the first electrode;
a first pixel electrode that is connected to the first electrode;
a second insulating film that is disposed in a layer lower than the first pixel electrode; and
a common electrode that is included in a layer lower than the second insulating film to overlap the first pixel electrode, wherein
the first switching component includes a second electrode that is a portion of the first line section, and
the common electrode includes an opening that surrounds the first electrode and an overlapping portion that overlaps the first connection electrode.

7. The array substrate according to claim 6, wherein
the opening of the common electrode includes a first slit and a second slit,
the first slit extends along the first direction toward the first connection electrode, and
the second slit extends along the first direction toward an opposite side from the first connection electrode and is longer than the first slit.

8. The array substrate according to claim 1, further comprising:
a first switching component including the first electrode;
a first pixel electrode that is connected to the first electrode;
a third line extending along the second direction and disposed on an opposite side from the first electrode with respect to the second line in the first direction and spaced from the second line;
a third electrode that is disposed on a same side as the first electrode with respect to the first line in the second direction and is spaced from the first line with respect to the second direction and is disposed between the second line and the third line in the first direction;
a second switching component including the third electrode; and
a second pixel electrode that is connected to the third electrode, wherein
the first switching component includes a second electrode that is a portion of the first line section,
the second switching component includes a fourth electrode that is a portion of the second line section,
the third line is a portion of the second conductive film that is different from the portions of the second conductive film configured as the first connection electrode, the second line, and the first electrode,
the third electrode is a portion of the second conductive film that is different from the portions of the second conductive film configured as the first connection electrode, the first source line, the first electrode, and the third line, and
the second line section crosses each of the second line and the third line via the first insulating film.

9. The array substrate according to claim 8, further comprising:
a fourth line that extends along the second direction and is disposed such that the first pixel electrode is between the fourth line and the second line with respect to the first direction;
a fifth line that extends along the second direction and is disposed on an opposite side from the second line with respect to the third line in the first direction and spaced from the third line;
a sixth line that extends along the second direction and is disposed on a third line side with respect to the fifth line with respect to the first direction and spaced from the fifth line;
a fifth electrode that is disposed on a same side as the first electrode with respect to the first line in the second direction and spaced from the first line and is between the fifth line and the sixth line in the first direction;
a third switching component including the fifth electrode;
a third pixel electrode that is disposed between the fifth line and the sixth line in the first direction and connected to the fifth electrode; and
a signal supply section configured to supply image signals to each of the second line, the third line, the fourth line, the fifth line, and the sixth line, wherein
the first line includes a third line section and a second connection electrode,
the third line section is a portion of the first conductive film that is different from the portions of the first conductive film configured as the first line section and the second line section,
the second connection electrode is a portion of the second conductive film that is different from the portions of the second conductive film configured as the first connection electrode, the second line, the first electrode, and the third line,
the fourth line is a portion of the second conductive film that is different from the portions of the second conductive film configured as the first connection electrode, the second line, the first electrode, the third line, and the second connection electrode,
the fifth line is a portion of the second conductive film that is different from the portions of the second conductive film configured as the first connection electrode, the second line, the first electrode, the third line, the second connection electrode, and the fourth line,
the sixth line is a portion of the second conductive film that is different from the portions of the second conductive film configured as the first connection electrode, the second line, the first electrode, the third line, the second connection electrode, the fourth line, and the fifth line,
the fifth electrode is a portion of the second conductive film that is different from the portions of the second conductive film configured as the first connection electrode, the second line, the first electrode, the third source line, the second connection electrode, the fourth line, the fifth line, and the sixth line,
the second line section includes a third end portion that is on an opposite side from the second end portion,
the third line section includes a fourth end portion that is disposed on a same side as the fifth electrode with respect to the third end portion in the second direction and is disposed between the fifth electrode and the fifth line with respect to the first direction,
the second connection electrode extends from the third end portion to the fourth end portion,
the first insulating film includes a third contact hole in a portion overlapping the third end portion and the second connection electrode and a fourth contact hole in a portion overlapping the fourth end portion and the second connection electrode,
the first switching component includes a sixth electrode that is a portion of the fourth line and a first semiconductor section that is made of semiconductor material and connected to the first electrode and the sixth electrode,
the third switching component includes a seventh electrode that is a portion of the second line section, an eighth electrode that is a portion of the sixth source line, and a third semiconductor section that is made of semiconductor material and connected to the fifth electrode and the sixth electrode, and
at least the image signals supplied from the signal supply section to the fourth line and the sixth line have opposite polarities.

10. A display device comprising:
the array substrate according to claim 1; and
an opposed substrate disposed opposite and spaced from the array substrate.
